(19) United States
(12) Patent Application Publication
(10) Pub. No.: US 2024/0105789 A1
(43) Pub. Date: Mar. 28, 2024

(54) SEMICONDUCTOR DEVICE INCLUDING A FIELD EFFECT TRANSISTOR

(71) Applicant: SAMSUNG ELECTRONICS CO., LTD., SUWON-SI (KR)

(72) Inventors: WONHYUK LEE, Suwon-Si (KR); SANGDUK PARK, Suwon-Si (KR); DONGSOO SEO, Suwon-Si (KR); JINWOOK LEE, Suwon-Si (KR)

(21) Appl. No.: 18/319,014

(22) Filed: May 17, 2023

(30) Foreign Application Priority Data
Sep. 28, 2022 (KR) 10-2022-0123746

(51) Int. Cl. H01L 29/417; H01L 27/092; H01L 29/06; H01L 29/423; H01L 29/45; H01L 29/775

(52) U.S. Cl. CPC H01L 29/41775; H01L 27/092; H01L 29/0673; H01L 29/42392; H01L 29/456; H01L 29/775

(57) ABSTRACT

Embodiments of the present inventive concepts provide a semiconductor device including a substrate that includes an active pattern, a channel pattern disposed on the active pattern, a first source/drain pattern and a second source/drain pattern that are connected to the plurality of semiconductor patterns, a gate electrode disposed on the plurality of semiconductor patterns, and a first active contact electrically connected to the first source/drain pattern and a second active contact electrically connected to the second source/drain pattern. In one aspect, the channel pattern includes a plurality of semiconductor patterns that are spaced apart from and vertically stacked on each other. In one aspect, the gate electrode includes inner electrodes disposed between neighboring semiconductor patterns of the plurality of semiconductor patterns and an outer electrode disposed on an uppermost semiconductor pattern.

### CROSS-REFERENCE TO RELATED APPLICATION

This U.S. nonprovisional application claims priority under 35 U.S.C § 119 to Korean Patent Application No. 10-2022-0123746, filed on Sep. 28, 2022, in the Korean Intellectual Property Office, the disclosure of which is incorporated by reference herein in its entirety.

### TECHNICAL FIELD

Embodiments of the present inventive concepts relate to a semiconductor device, and more particularly, to a semiconductor device including a field effect transistor.

### DISCUSSION OF RELATED ART

A semiconductor device includes an integrated circuit including metal oxide semiconductor field effect transistors (MOSFETs). As sizes and design rules of the semiconductor device gradually decrease, the sizes of the MOSFETs are also increasingly scaled down. The down scale of MOSFETs may deteriorate operating characteristics of the semiconductor device. Accordingly, various studies have been conducted to develop methods of fabricating semiconductor devices having superior performances while overcoming limitations caused by high integration of the semiconductor devices.

### SUMMARY

Embodiments of the present inventive concepts provides a semiconductor device including a substrate that includes an active pattern, and a channel pattern disposed on the active pattern, where the channel pattern includes a plurality of semiconductor patterns that are spaced apart from each other and are vertically stacked on each other. Embodiments of the present inventive concepts further provides a first source/drain pattern and a second source/drain pattern that are connected to the plurality of semiconductor patterns, where the first source/drain pattern is disposed on an NMOSFET region of a first active region and the second source/drain pattern is disposed on a PMOSFET region of a second active region. Embodiments of the present inventive concepts further provides a gate electrode disposed on the plurality of semiconductor patterns, where the gate electrode includes inner electrodes disposed between neighboring semiconductor patterns of the plurality of semiconductor patterns and an outer electrode disposed on an uppermost semiconductor pattern. Embodiments of the present inventive concepts further provides a first active contact electrically connected to the first source/drain pattern and a second active contact electrically connected to the second source/drain pattern, where a first recess depth of the first active contact is about 1.2 times to about 2.5 times as deep as a second recess depth of the second active contact.

Embodiments of the present inventive concepts further provides a semiconductor device including a substrate that includes an active pattern, and a channel pattern disposed on the active pattern, where the channel pattern includes a plurality of semiconductor patterns that are spaced apart from each other and are vertically stacked on each other. Embodiments of the present inventive concepts further provides a first source/drain pattern and a second source/drain pattern that are connected to the plurality of semiconductor patterns, where the first source/drain pattern is disposed on an NMOSFET region of a first active region, and the second source/drain pattern is disposed on a PMOSFET region of a second active region. Embodiments of the present inventive concepts further provides a gate electrode disposed on the plurality of semiconductor patterns, where the gate electrode includes inner electrodes disposed between neighboring semiconductor patterns of the plurality of semiconductor patterns and an outer electrode disposed on an uppermost semiconductor pattern. Embodiments of the present inventive concepts further provides a first active contact electrically connected to the first source/drain pattern and a second active contact electrically connected to the second source/drain pattern, where the inner electrodes include a first inner electrode, a second inner electrode, and a third inner electrode that are sequentially stacked. In one aspect, a bottom surface of the first active contact is disposed at a level lower than a level of a bottom surface of the third inner electrode, and a bottom surface of the second active contact is disposed at a level higher than the level of the bottom surface of the third inner electrode.

Embodiments of the present inventive concepts further provides a semiconductor device including a substrate that includes an active pattern, and a channel pattern disposed on the active pattern, where the channel pattern includes a plurality of semiconductor patterns that are spaced apart from each other and are vertically stacked on each other. Embodiments of the present inventive concepts further provides a source/drain pattern connected to the plurality of semiconductor patterns. Embodiments of the present inventive concepts further provides a gate electrode disposed on the plurality of semiconductor patterns, an active contact electrically connected to the source/drain pattern, and a metal line disposed on the active contact and the gate electrode. In one aspect the active contact includes a connection part that connects the metal line and the source/drain pattern, and a protrusion part inserted into the source/drain pattern and is electrically connected to the source/drain pattern. In one aspect, a width of the protrusion part decreases towards the substrate, and a level of a bottom surface of the protrusion part is lower than a level of a bottom surface of an uppermost semiconductor pattern of the plurality of semiconductor patterns.

### BRIEF DESCRIPTION OF THE DRAWINGS

FIGS. 1, 2, and 3 illustrate conceptual views showing logic cells of a semiconductor device according to some embodiments of the present inventive concepts.

FIG. 4 illustrates a plan view showing a semiconductor device according to some embodiments of the present inventive concepts.

FIGS. 5A, 5B, 5C, and 5D illustrate cross-sectional views respectively taken along lines A-A′, B-B′, C-C′, and D-D′, respectively, of FIG. 4.

FIG. 6A illustrates an enlarged view showing an example of section M depicted in FIG. 5A.

FIG. 6B illustrates an enlarged view showing an example of section N depicted in FIG. 5B.

FIGS. 7A, 7B, 8A, 8B, 9A, 9B, 9C, 10A, 10B, 10C, 11A, 11B, 11C, 11D, 12A, 12B, 12C, 12D, 13A, 13B, 13C, and 13D illustrate demonstrating a method of fabricating a semiconductor device in cross-sectional views according to some embodiments of the present inventive concepts.

FIG. 14 illustrates a cross-sectional view showing an active contact according to an embodiment of FIG. 5A.

FIGS. 15, 16, 17, 18, 19, and 20 illustrate a method of forming an active contact at the enlarged cross-sectional section M depicted in FIG. 14.

FIGS. 21A, 21B, 21C, and 21D illustrate cross-sectional views taken along lines A-A′, B-B′, C-C′, and D-D′, respectively, of FIG. 4 of a semiconductor device according to some embodiments of the present inventive concepts.

### DETAILED DESCRIPTION

Hereinafter, the inventive concept is described in more detail. Embodiments according to the present inventive concept will be described in more detail with reference to the accompanying drawings.

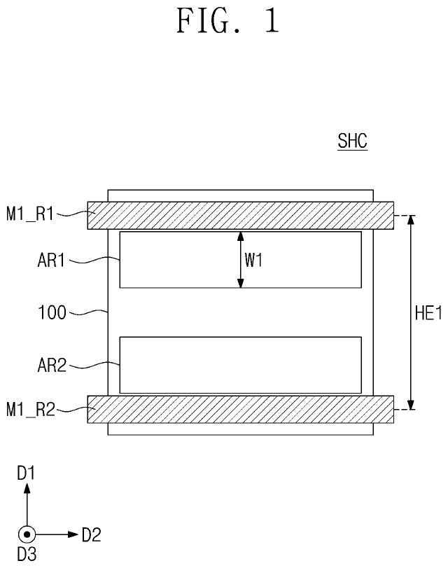

FIGS. 1 to 3 illustrate conceptual views showing logic cells of a semiconductor device according to some embodiments of the present inventive concepts.

Referring to FIG. 1, a single height cell SHC may be provided. For example, a substrate 100 may be disposed thereon with a first power line M1_R1 and a second power line M1_R2. The first power line M1_R1 may be a path for providing a source voltage VSS, for example, a ground voltage. The second power line M1_R2 may be a path for providing a drain voltage VDD, for example, a power voltage. For example, the first power line M1_R1 may be separated apart from the second power line M1_R2 in a first direction D1.

According to an embodiment, the single height cell SHC may be disposed between the first power line M1_R1 and the second power line M1_R2. The single height cell SHC may include one first active region AR1 and one second active region AR2. For example, one of the first and second active regions AR1 and AR2 may be a PMOSFET region, and the other of the first and second active regions AR1 and AR2 may be an NMOSFET region. For example, when first active region AR1 is a PMOSFET region, the second active region AR2 is an NMOSFET region, or vice versa. For example, the single height cell SHC may have a complementary metal oxide semiconductor (CMOS) structure disposed between the first power line M1_R1 and the second power line M1_R2.

Each of the first and second active regions AR1 and AR2 may have a first width W1 measured in a first direction D1. A first height HE1 is a length, measured in the first direction D1, of the single height cell SHC. The first height HE1 may be substantially the same as a distance (e.g., pitch) between the first power line M1_R1 and the second power line M1_R2.

The single height cell SHC may represent one logic cell. According to an aspect, the logic cell may include a logic device, such as AND, OR, XOR, XNOR, and inverter, that performs a specific function. For example, the logic cell may include transistors of a logic device and wiring lines that connect the transistors to each other.

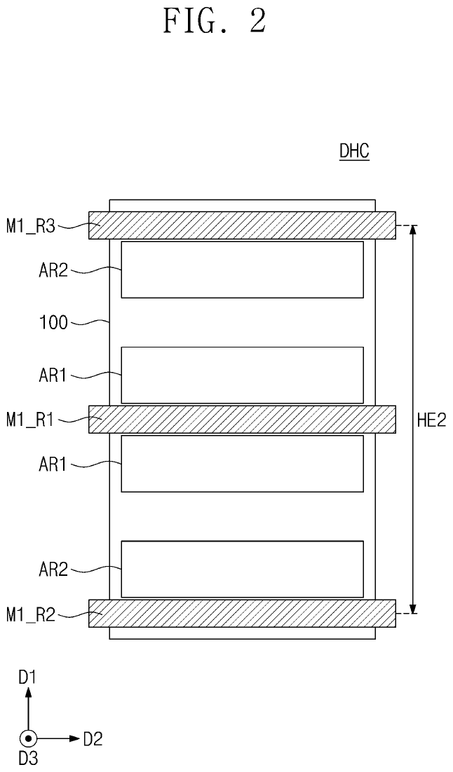

Referring to FIG. 2, a double height cell DHC may be provided. For example, a substrate 100 may be disposed thereon with a first power line M1_R1, a second power line M1_R2, and a third power line M1_R3. The first power line M1_R1 may be disposed between the second power line M1_R2 and the third power line M1_R3 in the first direction D1. The third power line M1_R3 may be a path for providing a drain voltage VDD.

According to an embodiment, the double height cell DHC may be disposed between the second power line M1_R2 and the third power line M1_R3. The double height cell DHC may include two first active regions AR1 and two second active regions AR2 spaced apart in the first direction D1.

For example, one of the two second active regions AR2 may be adjacent to the second power line M1_R2 and is disposed between the first power line M1_R1 and the second power line M1_R2. The other of the two second active regions AR2 may be adjacent to the third power line M1_R3 and is disposed between the first power line M1_R1 and the third power line M1_R3. The two first active regions AR1 may be adjacent to the first power line M1_R1. In a plan view, the first power line M1_R1 may be disposed between the two first active regions AR1.

A second height HE2 is a length, measured in the first direction D1, of the double height cell DHC. The second height HE2 may be about twice the first height HE1 of FIG. 1. The two first active regions AR1 of the double height cell DHC may be electrically and/or physically connected together to act as one active region (e.g., a first active region AR1).

In the present inventive concepts, the double height cell DHC shown in FIG. 2 may include a multi-height cell. For example, the multi-height cell may include a triple height cell whose cell height is about three times the cell height (e.g., the first height HE1) of the single height cell SHC.

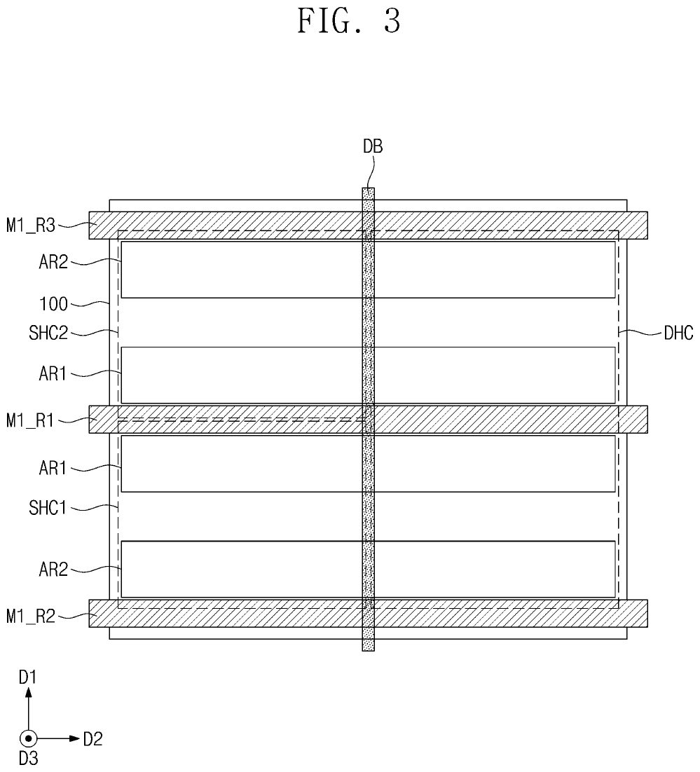

Referring to FIG. 3, a substrate 100 may be disposed thereon with a first single height cell SHC1, a second single height cell SHC2, and a double height cell DHC that are two-dimensionally disposed. For example, the first single height cell SHC1 is adjacent to the second single height cell SHC2 in the first direction D1, and the double height cell DHC is adjacent to the first single height cell SHC1 and the second single height cell SHC2 in the second direction D2. The first single height cell SHC1 may be disposed between a first power line M1_R1 and a second power line M1_R2. The second single height cell SHC2 may be disposed between the first power line M1_R1 and a third power line M1_R3. The second single height cell SHC2 may be adjacent to the first single height cell SHC1 in the first direction D1. For example, the first single height cell SHC1 and the second single height cell SHC2 may share the first power line M1_R1.

The double height cell DHC may be disposed between the second power line M1_R2 and the third power line M1_R3. The double height cell DHC may be adjacent to the first single height cell SHC1 and second single height cell SHC2 in the second direction D2.

A separation structure DB may be disposed between the first single height cell SHC1 and the double height cell DHC and between the second single height cell SHC2 and the double height cell DHC. The separation structure DB may electrically separate an active region of the double height cell DHC from an active region of each of the first single height cell SHC1 and second single height cell SHC2.

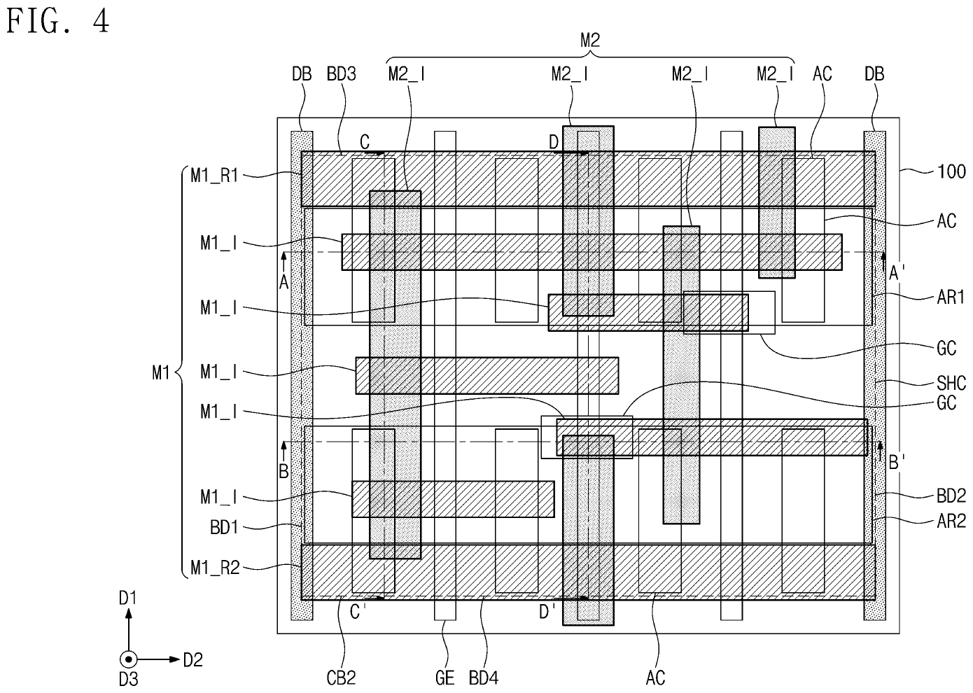

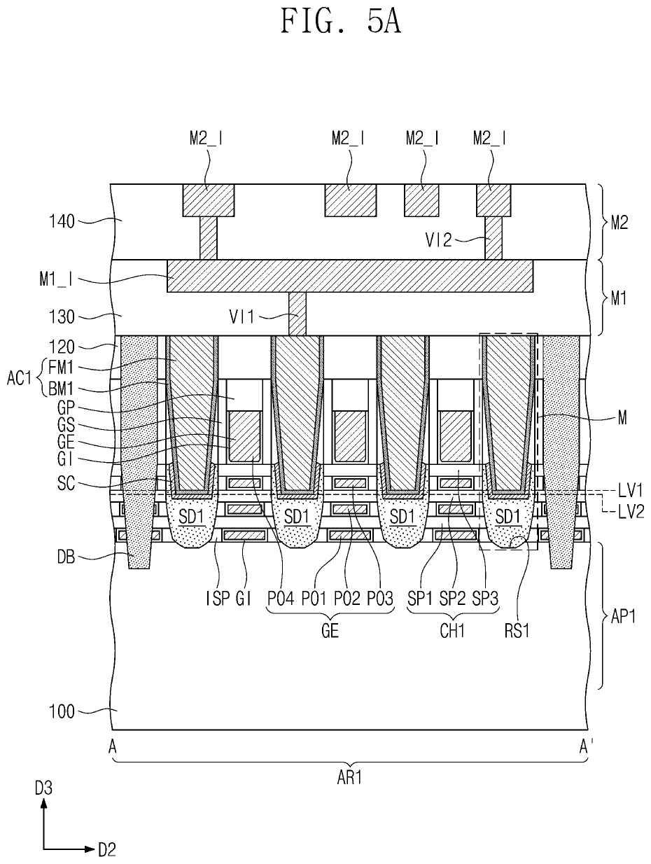

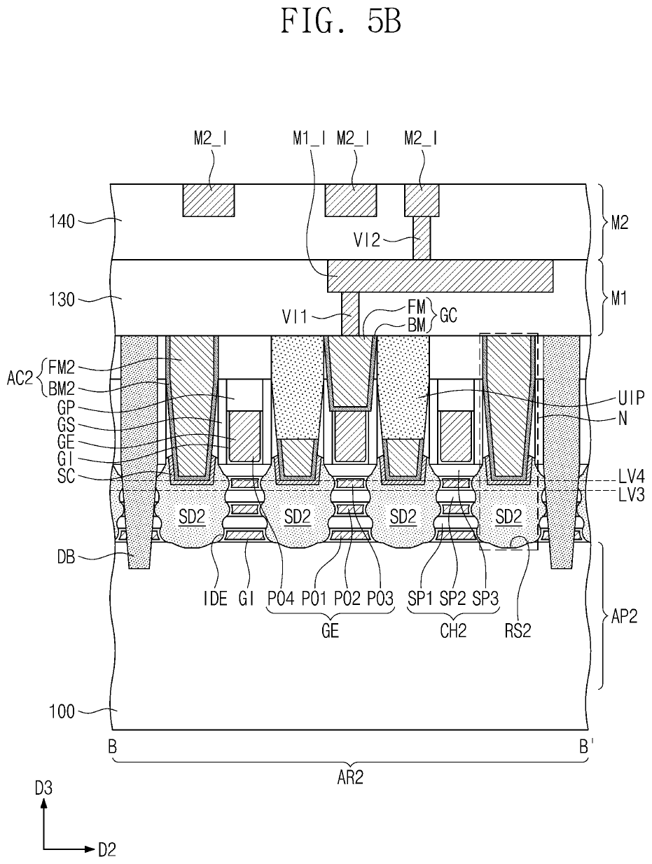

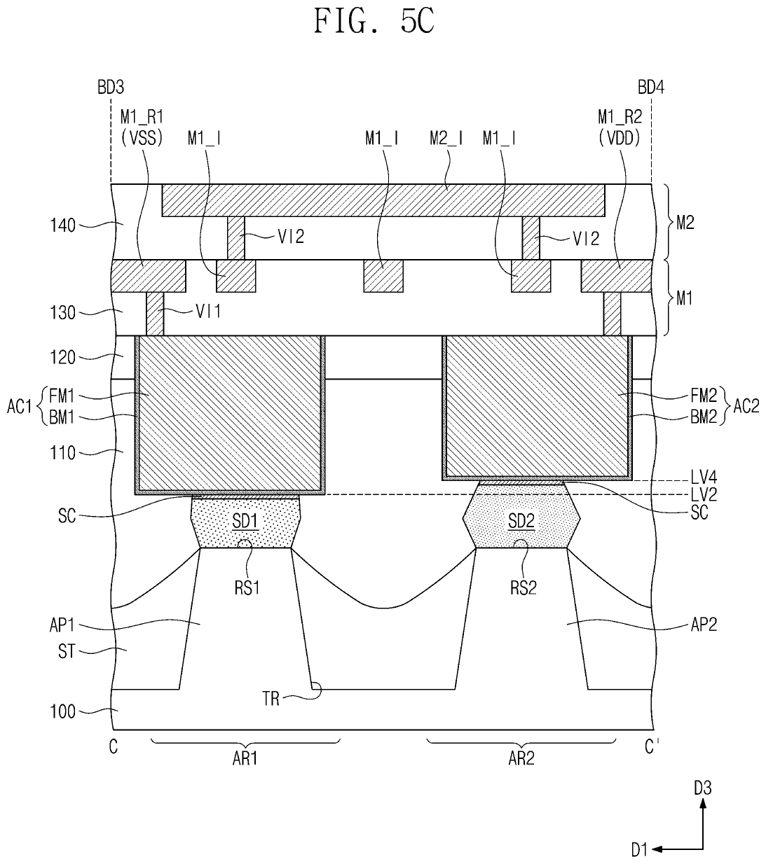

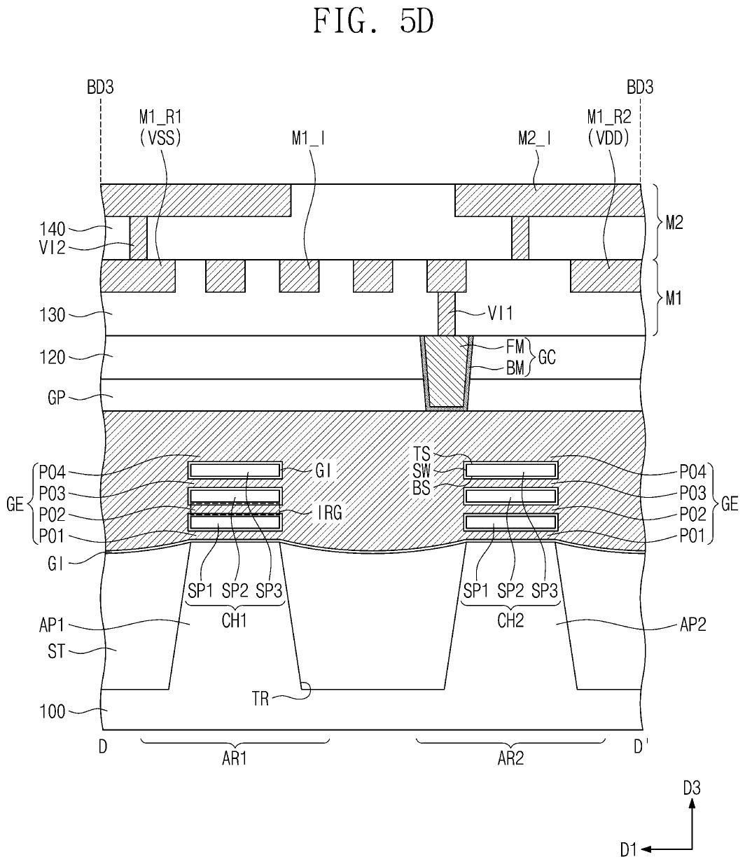

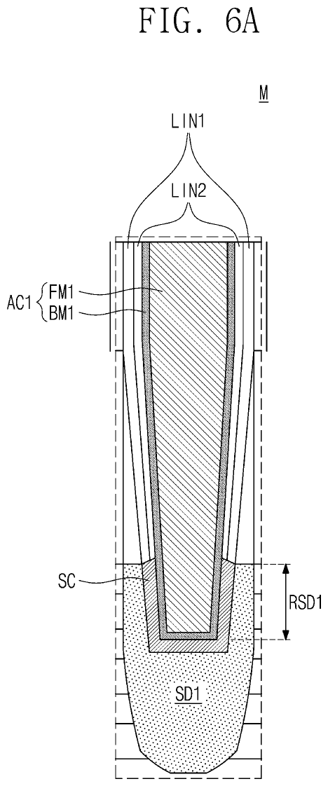

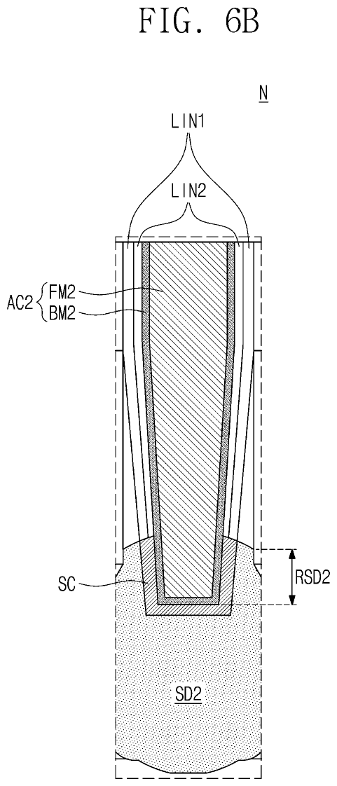

FIG. 4 illustrates a plan view showing a semiconductor device according to some embodiments of the present inventive concepts. FIGS. 5A, 5B, 5C, and 5D illustrate cross-sectional views respectively taken along lines A-A′, B-B′, C-C′, and D-D′ of FIG. 4. FIG. 6A illustrates an enlarged view showing an example of section M depicted in FIG. 5A. FIG. 6B illustrates an enlarged view showing an example of section N depicted in FIG. 5B. A semiconductor device depicted in FIGS. 4 and 5A to 5D is a detailed example of the single height cell SHC shown in FIG. 1.

Referring to FIGS. 4 and 5A to 5D, a single height cell SHC may be disposed on a substrate 100. The single height cell SHC may be disposed thereon with logic transistors included in a logic circuit. In some cases, the substrate 100 may be a compound semiconductor substrate or a semiconductor substrate including silicon, germanium, or silicon-germanium. For example, the substrate 100 may be a silicon substrate.

The substrate 100 may include a first active region AR1 and a second active region AR2 spaced apart in the first direction D1. Each of the first active region AR1 and second active region AR2 may extend in a second direction D2. In an embodiment, the first active region AR1 may be an NMOSFET region, and the second active region AR2 may be a PMOSFET region.

A first active pattern AP1 and a second active pattern AP2 may be separated by a trench TR formed on an upper portion of the substrate 100 (e.g., as shown in FIG. 5C). The first active pattern AP1 may be disposed on the first active region AR1, and the second active pattern AP2 may be disposed on the second active region AR2. The first active pattern AP1 and second active pattern AP2 may extend in the second direction D2. The first active pattern AP1 and second active pattern AP2 may be vertically protruding portions of the substrate 100.

A device isolation layer ST may be disposed on the substrate 100. The device isolation layer ST may fill the trench TR. For example, the device isolation layer ST may include a silicon oxide layer. The device isolation layer ST might not cover the first channel pattern CH1 and second channel pattern CH2 which will be discussed below.

As shown in FIG. 5D, a first channel pattern CH1 may be disposed on the first active pattern AP1. A second channel pattern CH2 may be disposed on the second active pattern AP2. Each of the first channel pattern CH1 and second channel pattern CH2 may include a first semiconductor pattern SP1, a second semiconductor pattern SP2, and a third semiconductor pattern SP3 that are sequentially stacked. For example, the third semiconductor pattern SP3 is disposed above the second semiconductor pattern SP2, and the second semiconductor pattern SP2 is disposed above the first semiconductor pattern SP1. The first semiconductor pattern SP1, second semiconductor pattern SP2, and third semiconductor pattern SP3 may be spaced apart from each other in a vertical direction (or a third direction D3).

For example, each of the first semiconductor pattern SP1, second semiconductor pattern SP2, and third semiconductor pattern SP3 may include silicon (Si), germanium (Ge), or silicon-germanium (SiGe). For example, each of the first semiconductor pattern SP1, second semiconductor pattern SP2, and third semiconductor pattern SP3 may include crystalline silicon, for example, monocrystalline silicon. In an embodiment of the present inventive concepts, the first semiconductor pattern SP1, second semiconductor pattern SP2, and third semiconductor pattern SP3 may be stacked nano-sheets.

As shown in FIG. 5A, a plurality of first source/drain patterns SD1 may be disposed on the first active pattern AP1. A plurality of first recesses RS1 may be formed on an upper portion of the first active pattern AP1. First source/drain patterns SD1 may be correspondingly disposed in the first recesses RS1. The first source/drain patterns SD1 may be impurity regions having a first conductivity type (e.g., n-type). The first channel pattern CH1 may be interposed between a pair of first source/drain patterns SD1. For example, the pair of first source/drain patterns SD1 may be connected (electrically or physically) to each other through the stacked first semiconductor pattern SP1, second semiconductor pattern SP2, and third semiconductor pattern SP3.

As shown in FIG. 5B, a plurality of second source/drain patterns SD2 may be disposed on the second active pattern AP2. A plurality of second recesses RS2 may be formed on an upper portion of the second active pattern AP2. Second source/drain patterns SD2 may be correspondingly disposed in the second recesses RS2. The second source/drain patterns SD2 may be impurity regions having a second conductivity type (e.g., p-type). The second channel pattern CH2 may be interposed between a pair of second source/drain patterns SD2. For example, the pair of second source/drain patterns SD2 may be connected to each other through the stacked first semiconductor pattern SP1, second semiconductor pattern SP2, and third semiconductor pattern SP3.

The first and second source/drain patterns SD1 and SD2 may be epitaxial patterns formed by a selective epitaxial growth (SEG) process. For example, each of the first source/drain pattern SD1 and second source/drain pattern SD2 may have a top surface higher than a top surface of the third semiconductor pattern SP3. For example, at least one of the first source/drain patterns SD1 and second source/drain pattern SD2 may have a top surface at substantially the same level as a top surface of the third semiconductor pattern SP3.

In an embodiment of the present inventive concepts, the first source/drain patterns SD1 may include the same semiconductor element (e.g., Si) as the semiconductor element of the substrate 100. The second source/drain patterns SD2 may include a semiconductor element (e.g., SiGe) having a lattice constant greater than the lattice constant of a semiconductor element of the substrate 100. As used herein, the phrase “lattice constant” refers to the constant distance between unit cells in a crystal lattice. Therefore, a pair of second source/drain patterns SD2 may provide the second channel pattern CH2 with compressive stress.

In an embodiment of the present inventive concepts, the second source/drain pattern SD2 may have a rugged embossing shape at a sidewall thereof. For example, the sidewall of the second source/drain pattern SD2 may have a wave-shape profile. The sidewall of the second source/drain pattern SD2 may protrude toward first inner electrode PO1, second inner electrode PO2, and third inner electrode PO3 of a gate electrode GE which will be discussed below.

As shown in FIGS. 5A and 5B, the first channel pattern CH1 and second channel pattern CH2 may be disposed thereon with gate electrodes GE. Edges of the gate electrodes GE may extend in a first direction D1 and crossing the first channel pattern CH1 and second channel pattern CH2. Each of the gate electrodes GE may vertically overlap the first channel pattern CH1 and second channel pattern CH2. The gate electrodes GE may be arranged at a first pitch in the second direction D2.

The gate electrode GE may include a first inner electrode PO1 interposed between the first semiconductor pattern SP1 and the active pattern (e.g., the first active pattern AP1 or the second active pattern AP2), a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 disposed on the third semiconductor pattern SP3.

Referring to FIG. 5D, the gate electrode GE surrounds the first semiconductor pattern SP1, second semiconductor pattern SP2, and third semiconductor pattern SP3. For example, the gate electrode GE may be disposed on a top surface TS, a bottom surface BS, and two opposite sidewalls SW of each of the first semiconductor pattern SP1, second semiconductor pattern SP2, and third semiconductor pattern SP3. For example, a transistor according to the present embodiment may be a three-dimensional field effect transistor (e.g., MBCFET or GAAFET) in which the gate electrode GE surrounds the first channel pattern CH1 and second channel pattern CH2 in three dimensions.

As shown in FIG. 5A, on the first active region AR1, inner spacers ISP may be correspondingly interposed between the first source/drain pattern SD1 and the first inner electrode PO1, second inner electrode PO2, and third inner electrode PO3 of the gate electrode GE. Each of the first inner electrode PO1, second inner electrode PO2, and third inner electrode PO3 of the gate electrode GE may be spaced apart from the first source/drain pattern SD1 by the inner spacer ISP in the second direction D2. The inner spacer ISP may prevent leakage current from the gate electrode GE.

Referring back to FIGS. 4 and 5A to 5D, a pair of gate spacers GS may be disposed on opposite sidewalls of the outer electrode PO4 of the gate electrode GE. The gate spacers GS may extend in the first direction D1 along the gate electrode GE. For example, the top surfaces of the gate spacers GS may be higher than a top surface of the gate electrode GE. For example, the top surfaces of the gate spacers GS may be coplanar with that of a first interlayer dielectric layer 110 which will be discussed below. In an embodiment, the gate spacers GS may include SiCN, SiCON, and/or SiN. In an embodiment, the gate spacers GS may include a multiple layer may be formed of two or more of SiCN, SiCON, and SiN. In an embodiment of the present inventive concepts, the gate spacer GS may include a silicon-containing dielectric material. The gate spacer GS may act as an etch stop layer when forming active contacts AC which will be discussed below. The gate spacers GS may cause that the active contacts AC to be formed in a self-alignment manner.

A gate capping pattern GP may be disposed on the gate electrode GE. For example, the gate capping pattern GP may be disposed on outer electrode PO4. The gate capping pattern GP may extend in the first direction D1 along the gate electrode GE. The gate capping pattern GP may include a material having an etch selectivity with respect to first interlayer dielectric layer 110 and second interlayer dielectric layer 120 which will be discussed below. For example, the gate capping pattern GP may include SiON, SiCN, SiCON, and/or SiN.

A gate dielectric layer GI may be interposed between the gate electrode GE and the first channel pattern CH1 and between the gate electrode GE. The gate dielectric layer GI may be interposed between the gate electrode GE and the second channel pattern CH2. The gate dielectric layer GI may cover the top surface TS, the bottom surface BS, and the opposite sidewalls SW of each of the first semiconductor pattern SP1, second semiconductor pattern SP2, and third semiconductor pattern SP3. The gate dielectric layer GI may cover a top surface of the device isolation layer ST, where the device isolation layer ST is disposed below the gate electrode GE.

In an embodiment of the present inventive concepts, the gate dielectric layer GI may include a silicon oxide layer, a silicon oxynitride layer, and/or a high-k dielectric layer. For example, the gate dielectric layer GI may have a structure in which a silicon oxide layer and a high-k dielectric layer are stacked. The high-k dielectric layer may include a high-k dielectric material whose dielectric constant is greater than a dielectric constant of a silicon oxide layer. For example, the high-k dielectric material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and/or lead zinc niobate.

According to some embodiments of the present inventive concepts, a semiconductor device includes a negative capacitance field effect transistor that uses a negative capacitor. For example, the gate dielectric layer GI may include a ferroelectric material layer that exhibits ferroelectric properties and a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to less than the capacitance of each capacitor. In contrast, when at least one of two or more capacitors connected in series has a negative capacitance, an overall capacitance may have a positive value greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to allow a transistor including the ferroelectric material layer to have a sub-threshold swing (SS) of less than about 60 mV/decade at room temperature.

The ferroelectric material layer may have ferroelectric properties. The ferroelectric material layer may include, for example, hafnium oxide, hafnium zirconium oxide, barium strontium titanium oxide, and/or lead zirconium titanium oxide. For example, the hafnium zirconium oxide may be a material in which hafnium oxide is doped with zirconium (Zr). For an example, the hafnium zirconium oxide may be a compound comprising hafnium (Hf), zirconium (Zr), and oxygen (O).

The ferroelectric material layer may further include impurities doped therein. For example, the impurities may include aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The type of impurities included in the ferroelectric material layer may be changed depending on what ferroelectric material is included in the ferroelectric material layer.

When the ferroelectric material layer includes hafnium oxide, the ferroelectric material layer may include impurities such as gadolinium (Gd), silicon (Si), zirconium (Zr), aluminum (Al), and/or yttrium (Y).

When the impurities are aluminum (Al), the ferroelectric material layer may include about 3 to 8 atomic percent aluminum. According to the present inventive concepts, the ratio of impurities may be a ratio of aluminum to the sum of hafnium and aluminum.

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to 7 atomic percent gadolinium. When the impurities are zirconium (Zr), the ferroelectric material layer may include about 50 to about 80 atomic percent zirconium. The atomic percent of impurities are based on the ratio of impurities to the sum of hafnium and the corresponding impurity.

The paraelectric material layer may have paraelectric properties. The paraelectric material layer may include, for example, silicon oxide and/or high-k metal oxide. The metal oxide included in the paraelectric material layer may include, for example, hafnium oxide, zirconium oxide, and/or aluminum oxide, but the present inventive concepts are not limited thereto.

The ferroelectric and paraelectric material layers may include the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from a crystal structure of the hafnium oxide included in the paraelectric material layer.

The ferroelectric material layer may have a thickness having ferroelectric properties. The thickness of the ferroelectric material layer may range, for example, from about 0.5 nm to about 10 nm, but inventive concepts are not limited thereto. Because ferroelectric materials have their own critical thickness that exhibits ferroelectric properties, the thickness of the ferroelectric material layer may depend on ferroelectric material.

For example, the gate dielectric layer GI may include a single ferroelectric material layer. For example, the gate dielectric layer GI may include a plurality of ferroelectric material layers that are spaced apart from each other in the vertical direction (e.g., the third direction D3). The gate dielectric layer GI may have a stack structure in which each ferroelectric material layer of a plurality of ferroelectric material layers is alternately stacked with each paraelectric material layer of a plurality of paraelectric material layers.

Referring to FIGS. 4 and 5A to 5D, the gate electrode Ge may include a first metal pattern and a second metal pattern disposed on the first metal pattern. The first metal pattern may be disposed on the gate dielectric layer GI and may be adjacent to the first semiconductor pattern SP1, second semiconductor pattern SP2, and third semiconductor pattern SP3. The first metal pattern may include a work-function metal that controls a threshold voltage of a transistor. A thickness and composition of the first metal pattern may be adjusted to achieve a desired threshold voltage of a transistor. For example, the first inner electrode PO1, second inner electrode PO2, and third inner electrode PO3 of the gate electrode GE may form a first metal pattern or a work-function metal.

The first metal pattern may include a metal nitride layer. For example, the first metal pattern may include nitrogen (N) and a metal such as titanium (Ti), tantalum (Ta), aluminum (Al), tungsten (W), and/or molybdenum (Mo). In addition, the first metal pattern may further include carbon (C). For example, the first metal pattern may include a plurality of stacked work-function metal layers.

The second metal pattern may include metal having resistance less than a resistance of the first metal pattern. For example, the second metal pattern may include tungsten (W), aluminum (Al), titanium (Ti), and/or tantalum (Ta). For example, the outer electrode PO4 of the gate electrode GE may include a first metal pattern and a second metal pattern disposed on the first metal pattern.

A first interlayer dielectric layer 110 may be disposed on the substrate 100. The first interlayer dielectric layer 110 may cover the gate spacers GS and the first source/drain pattern SD1 and second source/drain pattern SD2. The first interlayer dielectric layer 110 may have a top surface substantially coplanar with a top surface of the gate capping pattern GP and a top surface of the gate spacer GS. The first interlayer dielectric layer 110 may be disposed thereon with a second interlayer dielectric layer 120 that covers the gate capping pattern GP and gate spacer GS. For example, the second interlayer dielectric layer 120 may cover the first interlayer dielectric layer 110, the gate capping pattern GP, and gate spacer GS. A third interlayer dielectric layer 130 may be disposed on the second interlayer dielectric layer 120. A fourth interlayer dielectric layer 140 may be disposed on the third interlayer dielectric layer 130. For example, the first to fourth interlayer dielectric layers 110 to 140 may include a silicon oxide layer.

As shown in FIG. 4, the single height cell SHC may have a first boundary BD1 and a second boundary BD2 opposite to the first boundary BD1 in the second direction D2. The first boundary BD1 and second boundary BD2 may extend in the first direction D1. The single height cell SHC may have a third boundary BD3 and a fourth boundary BD4 opposite to the third boundary BD3 in the first direction D1. The third boundary DB3 and fourth boundary BD4 may extend in the second direction D2.

The single height cell SHC may be disposed on its opposite sides with a pair of separation structures DB opposite to each other in the second direction D2. For example, the pair of separation structures DB may be correspondingly disposed on first boundary BD1 and second boundary BD2 of the single height cell SHC. The separation structure DB may extend in the first direction D1 parallel to the gate electrodes GE. A pitch between the separation structure DB and corresponding adjacent gate electrode GE may be the same as the first pitch.

As shown in FIGS. 5A and 5B, the separation structure DB may penetrate the first interlayer dielectric layer 110 and second interlayer dielectric layer 120, and may extend into the first active pattern AP1 and second active pattern AP2. The separation structure DB may penetrate an upper portion of each of the first active pattern AP1 and second active pattern AP2. The separation structure DB may electrically separate an active region of the single height cell SHC from an active region of an adjacent cell (e.g., a second single height cell). In some cases, the separation structure DB may be covered by the third interlayer dielectric layer 130 and/or the fourth interlayer dielectric layer 140.

First active contact AC1 and second active contact AC2 may penetrate the first interlayer dielectric layer 110 and second interlayer dielectric layer 120. First active contact AC1 and second active contact AC2 may be electrically connected with the first source/drain pattern SD1 and second source/drain pattern SD2, respectively. A pair of active contacts (e.g., the first active contact AC1 and the second active contact AC2) may be disposed on opposite sides of the gate electrode GE. In a plan view, each of the first active contact AC1 and second active contact AC2 may have a bar shape that extends in the first direction D1.

The first active contact AC1 and second active contact AC2 may each be a self-aligned contact. For example, the gate capping pattern GP and the gate spacer GS may be used to form the first active contact AC1 and second active contact AC2 in a self-alignment manner. For example, the first active contact AC1 and second active contact AC2 may each cover at least a portion of a sidewall of the gate spacer GS. For example, the first active contact AC1 and second active contact AC2 may cover a portion of the top surface of the gate capping pattern GP.

A metal-semiconductor compound layer SC, such as a silicide layer, may be interposed between the first active contact AC1 and the first source/drain pattern SD1. The metal-semiconductor compound layer SC may be interposed between the second active contact AC2 and the second source/drain pattern SD2. The first active contact AC1 and second active contact AC2 may be electrically connected through the metal-semiconductor compound layers SC to the first source/drain pattern SD1 and second source/drain pattern SD2, respectively. For example, the metal-semiconductor compound layer SC may include of titanium silicide, tantalum silicide, tungsten silicide, nickel silicide, and/or cobalt silicide. The first active contact AC1 and second active contact AC2 according to the present inventive concepts will be further discussed in detail below with reference to FIGS. 5A to 5C, 6A, and 6B.

As shown in FIGS. 5B and 5D, the gate contacts GC may penetrate the second interlayer dielectric layer 120 and the gate capping pattern GP, and is electrically connected to the gate electrodes GE. In a plan view, the gate contacts GC may be disposed to correspondingly overlap the first active region AR1 and the second active region AR2. For example, the gate contact GC may be disposed on the second active pattern AP2 (see FIG. 5B).

In an embodiment of the present inventive concepts, referring to FIG. 5B, the gate contact GC may have an upper portion adjacent to the gate contact GC, and the upper portion of the gate contact GC may be filled with an upper dielectric pattern UIP. The upper dielectric pattern UIP may have a bottom surface lower than that of the gate contact GC. For example, the upper dielectric pattern UIP is configured so that the second active contact AC2 adjacent to the gate contact GC has a top surface lower than the bottom surface of the gate contact GC. Therefore, it may be possible to prevent an electrical short-circuit caused by contact between the gate contact GC and adjacent second active contact AC2.

The first active contact AC1 may include a first conductive pattern FM1 and a first barrier pattern BM1 that surrounds the first conductive pattern FM1. The second active contact AC2 may include a second conductive pattern FM2 and a second barrier pattern BM2 that surrounds the second conductive pattern FM2. The first barrier pattern BM1 and the second barrier pattern BM2 may be disposed on metal-semiconductor compound layer SC, and are disposed on first source/drain pattern SD1 and second source/drain pattern SD2, respectively. The gate contact GC may include a conductive pattern FM and a barrier pattern BM that surrounds the conductive pattern FM. For example, the first conductive pattern FM1, second conductive pattern FM2, and conductive pattern FM may each include of aluminum, copper, tungsten, molybdenum, and/or cobalt. The first barrier pattern BM1, second barrier pattern BM2, and barrier pattern BM may cover sidewalls and bottom surfaces of the first conductive pattern FM1, second conductive pattern FM2, and conductive pattern FM, respectively. The first barrier pattern BM1, conductive pattern BM2, and conductive pattern BM may each include a metal layer and a metal nitride layer. The metal layer may include of titanium, tantalum, tungsten, nickel, cobalt, and/or platinum. The metal nitride layer may include of a titanium nitride (TiN) layer, a tantalum nitride (TaN) layer, a tungsten nitride (WN) layer, a nickel nitride (NiN) layer, a cobalt nitride (CoN) layer, and/or a platinum nitride (PtN) layer.

A first metal layer M1 may be disposed in the third interlayer dielectric layer 130. For example, the first metal layer M1 may include a first power line M1_R1, a second power line M1_R2, and first wiring lines M1_I. The lines M1_R1, M1_R2, and M1_I of the first metal layer M1 may extend in parallel to each other in the second direction D2.

For example, the first and second power lines M1_R1 and M1_R2 may be respectively disposed on the third and fourth boundaries BD3 and BD4 of the single height cell SHC. The first power line M1_R1 may extend in the second direction D2 along the third boundary BD3. The second power line M1_R2 may extend in the second direction D2 along the fourth boundary BD4.

The first wiring lines M1_I of the first metal layer M1 may be disposed between the first power line M1_R1 and second power line M1_R2 along the first direction D1. The first wiring lines M1_I of the first metal layer M1 may be arranged at a second pitch along the first direction D1. The second pitch may be less than the first pitch. Each of the first wiring lines M1_I may have a line-width less than a line-width of each of the first power line M1_R1 and second power line M1_R2.

The first metal layer M1 may further include first vias VI1. The first vias VI1 may be correspondingly disposed below the first power line M1_R1, second power line M1_R2, and first wiring lines M1_I of the first metal layer M1. The first via VI1 may electrically connect the active contact AC to one of the first power line M1_R1, second power line M1_R2, and first wiring lines M1_I of the first metal layer M1. The first via VI1 may electrically connect the gate contact GC to one of the first power line M1_R1, second power line M1_R2, and first wiring lines M1_I of the first metal layer M1.

A certain line (either a wiring line or a power line) and corresponding first via VI1 disposed below the certain line of the first metal layer M1 may be formed by individual processes. For example, the certain line and the corresponding first via VI1 of the first metal layer M1 may each be formed by a single damascene process. according to some embodiments, a sub-20 nm process may be employed to fabricate a semiconductor device.

A second metal layer M2 may be disposed in the fourth interlayer dielectric layer 140. The second metal layer M2 may include a plurality of second wiring lines M2_I. The second wiring lines M2_I of the second metal layer M2 may each have a linear or bar shape that extends in the first direction D1. For example, the second wiring lines M2_I may parallelly extend with respect to each other in the first direction D1.

The second metal layer M2 may further include second vias VI2 that are correspondingly disposed below the second wiring lines M2_I. A certain line of the first metal layer M1 may be electrically connected to a corresponding line of the second metal layer M2 through the second via VI2. For example, a second wiring line M2_I and the corresponding second via VI2 disposed below the second wiring line M2_I of the second metal layer M2 may be simultaneously formed by a dual damascene process.

The first metal layer M1 and second metal layer M2 may have wiring lines that include the same or different conductive materials. For example, the wiring lines of the first metal layer M1 and second metal layer M2 may include metallic material such as aluminum, copper, tungsten, molybdenum, ruthenium, and/or cobalt. For example, other metal layers (e.g., M3, M4, M5, etc.) may be additionally stacked on the fourth interlayer dielectric layer 140. Each of the stacked metal layers may include wiring lines for routing between cells.

The first active contact AC1 and second active contact AC2 will be further discussed in detail below with reference to FIGS. 5A to 5C, 6A, and 6B. The first active contact AC1 may include a first conductive pattern FM1 and a first barrier pattern BM1 that surrounds the first conductive pattern FM1. For example, the first barrier pattern BM1 may surround two opposite sidewalls and a bottom surface of the first conductive pattern FM1. The first active contact AC1 may vertically overlap the first source/drain pattern SD1. The first active contact AC1 may be electrically connected to the first source/drain pattern SD1. For example, the first active contact AC1 may have a lower part that is inserted into the first source/drain pattern SD1, and the lower part of the first active contact AC1 and the first source/drain pattern SD1 may be in contact with each other through a recession.

A silicide layer SC may be interposed between the first active contact AC1 and the first source/drain pattern SD1. The silicide layer SC may be a metal-semiconductor compound layer. The silicide layer SC may reduce a contact resistance between the first active contact AC1 and the first source/drain pattern SD1. For example, the first active contact AC1 may be electrically connected through the silicide layer SC to the first source/drain pattern SD1.

Referring to FIG. 6A, the first source/drain pattern SD1 may have a recess region formed by performing an etching process. The first active contact AC1 may be inserted through the recess region into the first source/drain pattern SD1. The recess region may define a first recess depth RSD1 of the first source/drain pattern SD1. The first recess depth RSD1 may be a depth to which the first active contact AC1 is inserted into the first source/drain pattern SD1. For example, the first recess depth RSD1 may indicate a distance from a top surface of the first source/drain pattern SD1 to a bottom surface of the first active contact AC1. The bottom surface of the first active contact AC1 may correspond to the bottom surface of the first barrier pattern BM1.

The first barrier pattern BM1 may cover lateral and bottom surfaces of the first conductive pattern FM1. The bottom surface and a portion of a lateral surface (e.g., two opposite sidewalls) of the first barrier pattern BM1 may be in contact with the silicide layer SC. One or more liner layers (e.g., LIN1 and LIN2) may be disposed on a remaining portion of the lateral surface of the first barrier pattern BM1 which is not in contact with the silicide layer SC. The liner layers LIN1 and LIN2 may include silicon oxide, silicon nitride, or silicon oxynitride. Each of the liner layers LIN1 and LIN2 may have a thickness of about 5 Å to about 15 Å. The liner layers LIN1 and LIN2 may be layers that remain on a sidewall of the recess region after a cyclic etching process.

The second active contact AC2 may include a second conductive pattern FM2 and a second barrier pattern BM2 that surrounds the second conductive pattern FM2. For example, the second barrier pattern BM2 may surround two opposite sidewalls and a bottom surface of the second conductive pattern FM2. The second active contact AC2 may vertically overlap the second source/drain pattern SD2. The second active contact AC2 may be electrically connected to the second source/drain pattern SD2. For example, the second active contact AC2 may have a lower part that is inserted into the second source/drain pattern SD2, and the lower part of the second active contact AC2 and the second source/drain pattern SD2 may be in contact with each other through a recession.

A silicide layer SC may be interposed between the second active contact AC2 and the second source/drain pattern SD2. The silicide layer SC may be a metal-semiconductor compound layer. The silicide layer SC may reduce a contact resistance between the second active contact AC2 and the second source/drain pattern SD2. For example, the second active contact AC2 may be electrically connected through the silicide layer SC to the second source/drain pattern SD2.

Referring to FIG. 6B, the second source/drain pattern SD2 may have a recess region formed by performing an etching process. The second active contact AC2 may be inserted through the recess region into the second source/drain pattern SD2. The recess region may define a second recess depth RSD2 of the second source/drain pattern SD2. The second recess depth RSD2 may be a depth to which the second active contact AC2 is inserted into the second source/drain pattern SD2. For example, the second recess depth RSD2 may indicate a distance from a lower level of a top surface of the second source/drain pattern SD2 to a bottom surface of the second active contact AC2. The bottom surface of the second active contact AC2 may correspond to the bottom surface of the second barrier pattern BM2.

The second barrier pattern BM2 may cover lateral (e.g., sidewalls) and bottom surfaces of the second conductive pattern FM2. The bottom surface and a portion of a lateral surface of the second barrier pattern BM2 may be in contact with the silicide layer SC. One or more liner layers (e.g., LIN1 and LIN2) may be disposed on a remaining portion of the lateral surface of the second barrier pattern BM2 which is not in contact with the silicide layer SC. The liner layers LIN1 and LIN2 may include silicon oxide, silicon nitride, or silicon oxynitride. Each of the liner layers LIN1 and LIN2 may have a thickness of about 5 Å to about 15 Å. The liner layers LIN1 and LIN2 may be layers that remain on a sidewall of the recess region after a cyclic etching process.

Referring to FIGS. 6A and 6B, the first recess depth RSD1 may be greater than the second recess depth RSD2. The first recess depth RSD1 may be about 1.2 times to about 2.5 times the second recess depth RSD2. For example, the first recess depth RSD1 may be about 1.5 times to about 2 times the second recess depth RSD2. Alternatively, the first recess depth RSD1 may be range from about 10.0 nm to about 12.0 nm. The second recess depth RSD2 may range from about 5.0 nm to about 7.0 nm.

A subsequently described cyclic etching process may be performed to adjust the first recess depth RSD1 and second recess depth RSD2 to corresponding target values. For example, the first recess depth RSD1 of the first source/drain pattern SD1 provided on an NMOSFET region may be adjusted to have greater depth than the second recess depth RSD2 of the second source/drain pattern SD2 provided on a PMOSFET region.

Referring back to FIGS. 5A to 5C, the bottom surface of the first active contact AC1 may be lower than that of the third inner electrode PO3. The bottom surface of the first active contact AC1 may correspond to the bottom surface of the first barrier pattern BM1, and the bottom surface of the first barrier pattern BM1 may be lower than the bottom surface of the third inner electrode PO3. For example, a first level LV1 may represent a position level in the third direction D3 of a bottom surface of the gate dielectric layer GI that surrounds the third inner electrode PO3. For example, the first level LV1 may be a position level in the third direction D3 of a surface on which the bottom surface of the gate dielectric layer GI that surrounds the third inner electrode PO3 is coplanar with bottom surfaces of the inner spacers ISP adjacent to a lateral surface of the gate dielectric layer GI that surrounds the third inner electrode PO3.

A second level LV2 may represent a position level in the third direction D3 of the bottom surface of the first active contact AC1. For example, the second level LV2 may be the position level of a bottom surface of the first barrier pattern BM1 of the first active contact AC1. The second level LV2 may be lower than the first level LV1. For example, the second level LV2 may be located lower in the third direction D3 than the first level LV1. For example, the bottom surface of the first active contact AC1 may be lower than the bottom surface of the gate dielectric layer GI that surrounds the third inner electrode PO3.

The bottom surface of the second active contact AC2 may be higher than the bottom surface of the third inner electrode PO3. The bottom surface of the second active contact AC2 may correspond to the bottom surface of the second barrier pattern BM2, and the bottom surface of the second barrier pattern BM2 may be disposed at a higher level than the bottom surface of the third inner electrode PO3. In addition, the bottom surface of the second active contact AC2 may be higher than the bottom surface of the third inner electrode PO3 and lower than a top surface of the third inner electrode PO3. For example, the bottom surface of the second active contact AC2 may be disposed at a level between the bottom surface of the third inner electrode PO3 and lower than a top surface of the third inner electrode PO3 in the third direction D3.

A third level LV3 may represent a position level in the third direction D3 of the bottom surface of the gate dielectric layer GI that surrounds the third inner electrode PO3. For example, the third level LV3 may be a position level in the third direction D3 of a surface on which the bottom surface of the gate dielectric layer GI that surrounds the third inner electrode PO3 is coplanar with bottom surfaces of the inner spacers ISP adjacent to the lateral surface of the gate dielectric layer GI that surrounds the third inner electrode PO3. In an embodiment, the third level LV3 may be the same as the first level LV1 of FIG. 5A.

A fourth level LV4 may represent a position level in the third direction D3 of the bottom surface of the second active contact AC2. For example, the fourth level LV4 may be the position level of a bottom surface of the second barrier pattern BM2 of the second active contact AC2. The fourth level LV4 may be higher than the third level LV3. For example, the fourth level LV4 may be located higher, in the third direction D3, than the third level LV3. For example, the bottom surface of the second active contact AC2 may be higher than the bottom surface of the gate dielectric layer GI that surrounds the third inner electrode PO3. In addition, the bottom surface of the second active contact AC2 may be higher than the bottom surface of the gate dielectric layer GI that surrounds the third inner electrode PO3 and lower than a top surface of the gate dielectric layer GI that surrounds the third inner electrode PO3.

Referring back to FIG. 5C, the second level LV2 may be lower than the fourth level LV4. For example, the bottom surface of the first active contact AC1 may be lower than the bottom surface of the second active contact AC2. For example, the bottom surface of the first barrier pattern BM1 of the first active contact AC1 may be lower than the bottom surface of the second barrier pattern BM2 of the second active contact AC2. This level difference may be caused by the different recess depth, where the first recess depth RSD1 of FIG. 6A is greater than the second recess depth RSD2 of FIG. 6B.

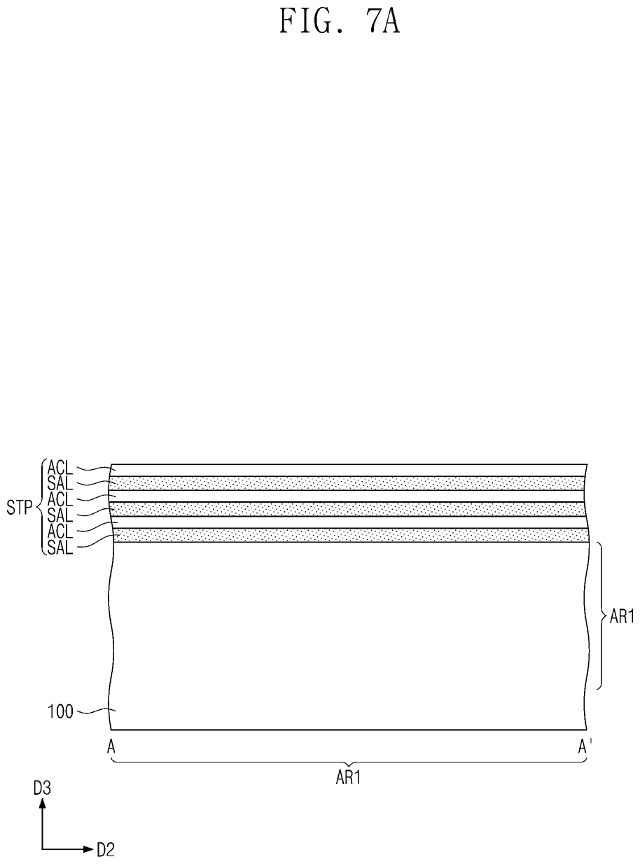

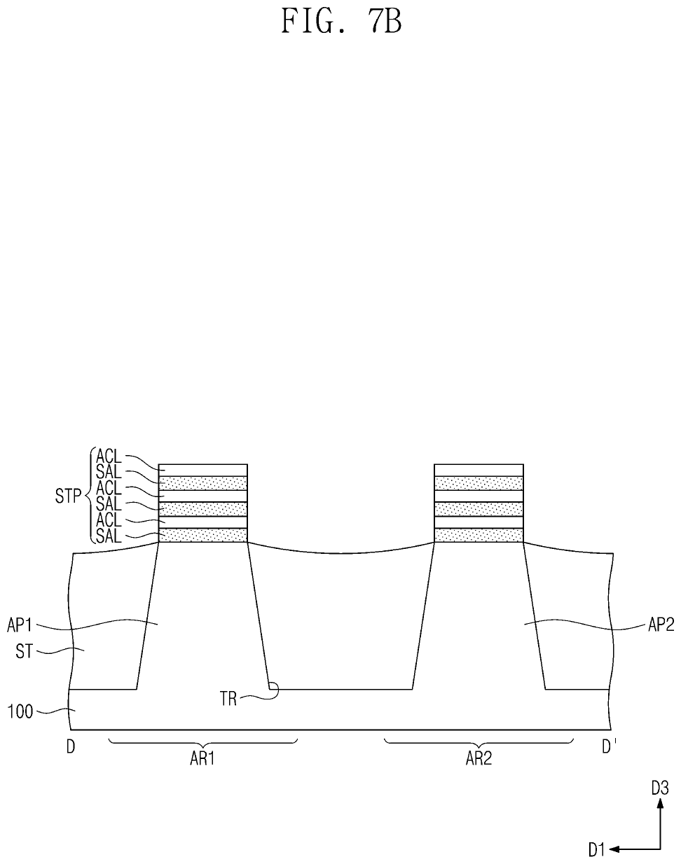

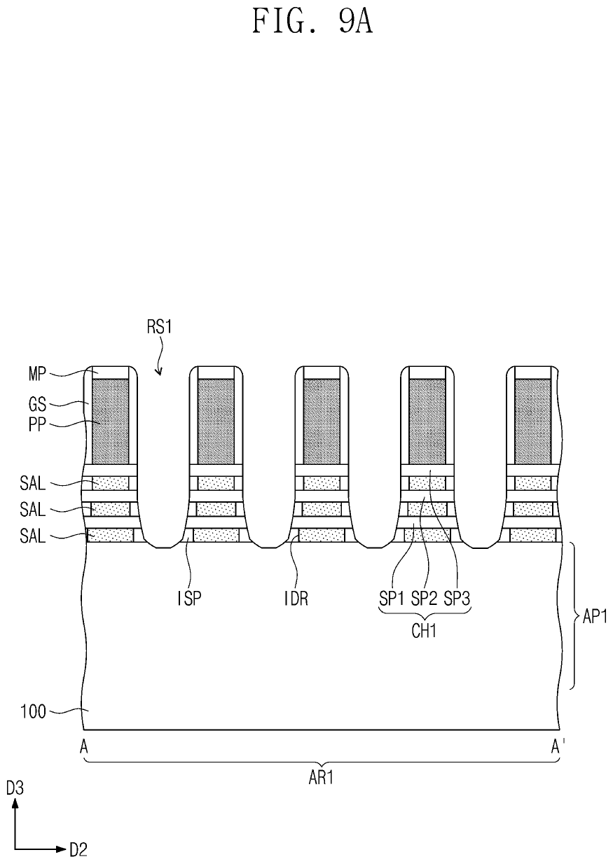

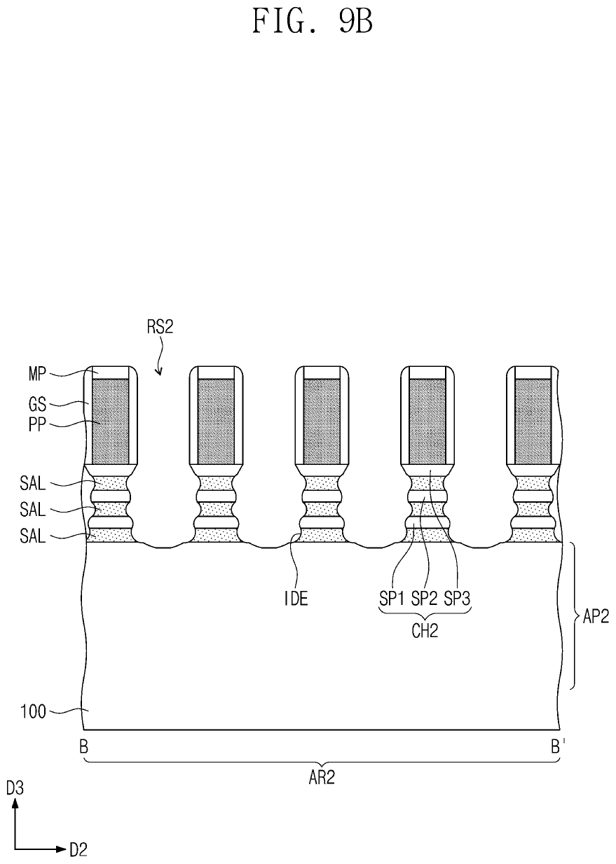

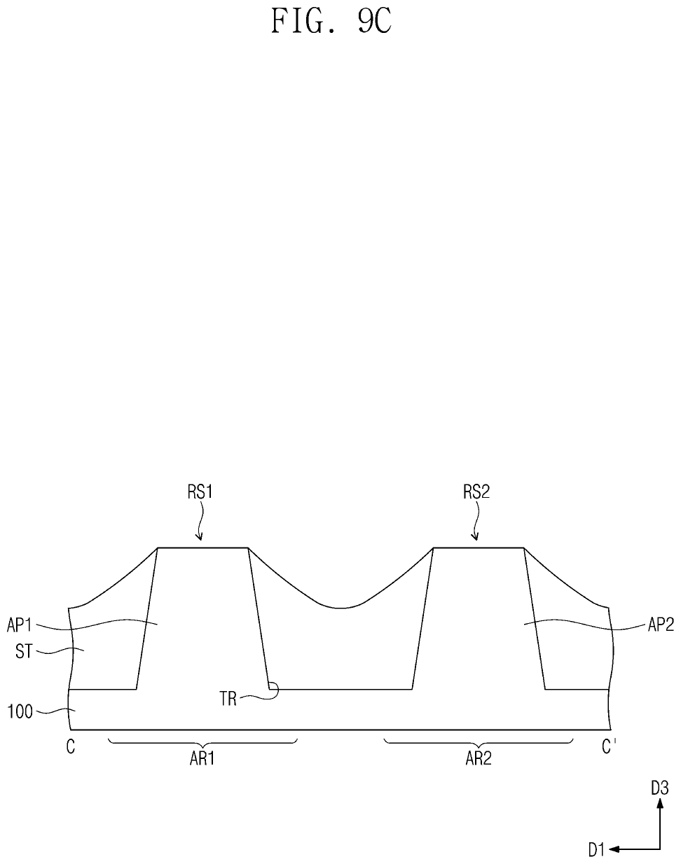

FIGS. 7A to 13D illustrate a method of fabricating a semiconductor device in cross-sectional views according to some embodiments of the present inventive concepts. For example, FIGS. 7A, 8A, 9A, 10A, 11A, and 12A illustrate cross-sectional views taken along line A-A′ of FIG. 4. FIGS. 9B, 10B, 11B, 12B, and 13B illustrate cross-sectional views taken along line B-B′ of FIG. 4. FIGS. 9C, 10C, 11C, 12C, and 13C illustrate cross-sectional views taken along line C-C′ of FIG. 4. FIGS. 7B, 8B, 11D, 12D, and 13D illustrate cross-sectional views taken along line D-D′ of FIG. 4.

Referring to FIGS. 7A and 7B, a substrate 100 may be provided which includes a first active region AR1 and a second active region AR2. Active layers ACL and sacrificial layers SAL may be alternately stacked on the substrate 100. For example, a sacrificial layer SAL may be disposed between an active layer ACL and the substrate 100. The active layers ACL may include one of silicon (Si), germanium (Ge), or silicon-germanium (SiGe), and the sacrificial layers SAL may include one of silicon (Si), germanium (Ge), or silicon-germanium (SiGe). For example, the active layers ACL may include a different material than the material of the sacrificial layers SAL.

The sacrificial layer SAL may include a material having an etch selectivity with respect to the active layer ACL. For example, the active layers ACL may include silicon (Si), and the sacrificial layers SAL may include silicon-germanium (SiGe). Each of the sacrificial layers SAL may have a germanium concentration of about 10 at % to about 30 at %. As used herein, the unit “at %” refers to the atomic percentage. For example, Each of the sacrificial layers SAL may have a germanium concentration of about 10 at % to about 30 at % and a silicon concentration of about 90 at % to about 70 at %.

Mask patterns may be formed on each of the first and second active regions AR1 and AR2 of the substrate 100. The mask pattern may have a linear or bar shape that extends in a second direction D2.

A patterning process may be performed in which the mask patterns are used as an etching mask to form a trench TR that defines a first active pattern AP1 and a second active pattern AP2. The first active pattern AP1 may be formed on the first active region AR1. The second active pattern AP2 may be formed on the second active region AR2.

A stack pattern STP may be formed on each of the first pattern AP1 and second active pattern AP2. The stack pattern STP may include the active layers ACL and the sacrificial layers SAL that are alternately stacked. During the patterning process, the stack pattern STP may be formed together with the first active pattern AP1 and second active pattern AP2.

A device isolation layer ST may be formed to fill the trench TR between the first active pattern AP1 and the second active pattern AP2. For example, a dielectric layer may be formed on an entire surface of the substrate 100 to cover the stack patterns STP, the first active pattern AP1, and the second active pattern AP2. The dielectric layer may be recessed until the stack patterns STP are exposed, and thus the device isolation layer ST may be formed.

The device isolation layer ST may include a dielectric material, such as a silicon oxide layer. The stack patterns STP may be exposed upwardly from the device isolation layer ST. For example, the stack patterns STP may vertically protrude upwards from the device isolation layer ST.

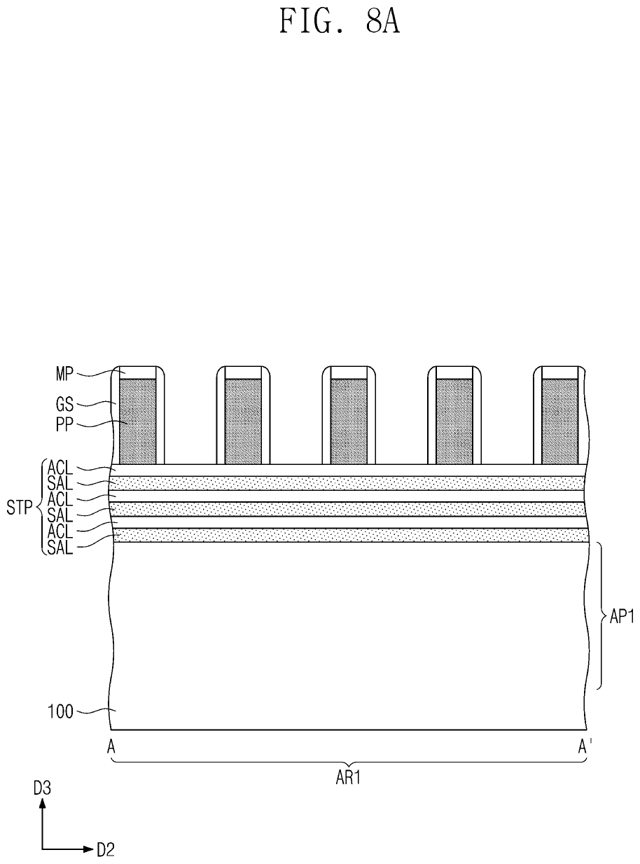

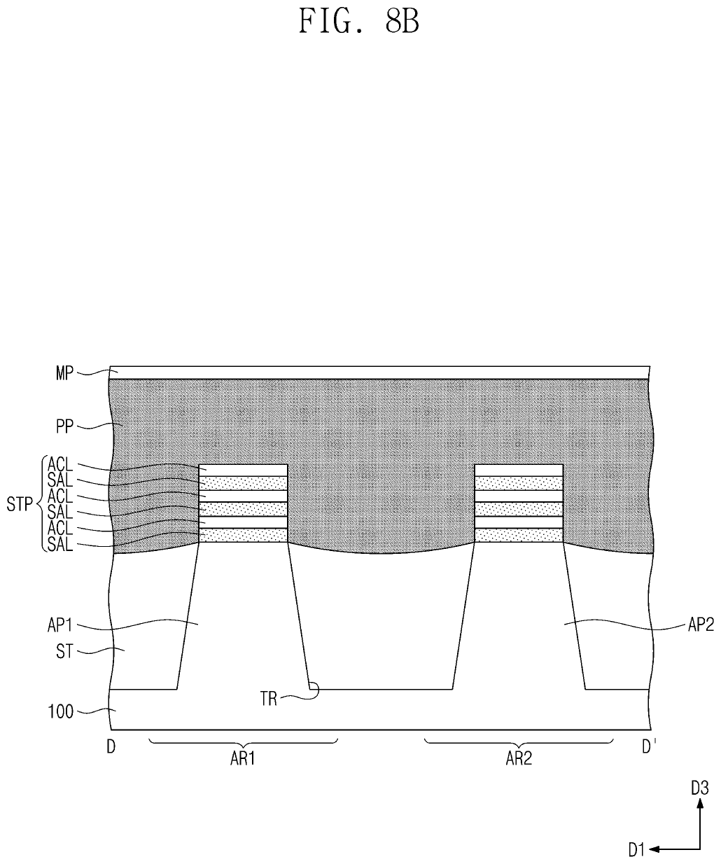

Referring to FIGS. 8A and 8B, sacrificial patterns PP may be formed on the substrate 100, and running across the stack patterns STP. Each of the sacrificial patterns PP may be formed to have a linear or bar shape that extends in a first direction D1. The sacrificial patterns PP may be arranged at a first pitch along the second direction D2.

For example, the formation of the sacrificial patterns PP may include forming a sacrificial layer on the entire surface of the substrate 100, forming hardmask patterns MP on the sacrificial layer, and using the hardmask patterns MP as an etching mask to pattern the sacrificial layer. For example, the sacrificial patterns PP may cover the stack patterns STP, the device isolation layer ST, the first active pattern AP1, and the second active pattern AP2. The sacrificial layer may include polysilicon.

A pair of gate spacers GS may be formed on opposite sidewalls of each of the sacrificial patterns PP in the second direction. The formation of the gate spacers GS may include conformally forming a gate spacer layer on the entire surface of the substrate 100 and anisotropically etching the gate spacer layer. In an embodiment of the present inventive concepts, the gate spacer GS may be a multiple layer including at least two layers.

Referring to FIGS. 9A to 9C, first recesses RS1 may be formed in the stack pattern STP on the first active pattern AP1. Second recesses RS2 may be formed in the stack pattern STP on the second active pattern AP2. During the formation of the first recesses RS1 and second recesses RS2, the device isolation layer ST may further be recessed on opposite sides of each of the first active pattern AP1 and second active pattern AP2 (see FIG. 9C).

For example, the hardmask patterns MP and the gate spacers GS may be used as an etching mask such that the stack pattern STP on the first active pattern AP1 may be etched to form the first recesses RS1. For example, the hardmask patterns MP and the gate spacers GS may be used to guide the formation of first recesses RS1. The first recesses RS1 may be formed between a pair of sacrificial patterns PP.

The active layers ACL may be formed into first semiconductor pattern SP1, second semiconductor pattern SP2, and third semiconductor pattern SP3 that are sequentially stacked between two neighboring first recesses RS1. A first channel pattern CH1 may include first semiconductor pattern SP1, second semiconductor pattern SP2, and third semiconductor pattern SP3 between two neighboring first recesses RS1.

The first recess RS1 may be formed between neighboring sacrificial patterns PP. A width, measured in the second direction D2, of the first recess RS1 may decrease when the first recess RS1 is closer to the substrate 100.

The first recess RS1 may expose the sacrificial layers SAL. A selective etching process may be performed on the exposed sacrificial layers SAL. The etching process may include a wet etching process that selectively etches silicon-germanium. In the etching process, each of the sacrificial layers SAL may be indented to form an indent region IDR. The indent region IDR may allow the sacrificial layer SAL to have a concave sidewall. A dielectric layer may be formed in the first recess RS1, filling the indent regions IDR. The sacrificial layers SAL and the first semiconductor pattern SP1, second semiconductor pattern SP2, and third semiconductor pattern SP3 exposed by the first recess RS1 may become a seed layer for the dielectric layer. The dielectric layer may be a crystalline dielectric layer grown on a crystalline semiconductor included in the sacrificial layers SAL and the first semiconductor pattern SP1, second semiconductor pattern SP2, and third semiconductor pattern SP3.

An inner spacer ISP may be formed to fill the indent region IDR. For example, the formation of the inner spacer ISP may include wet-etching an epitaxial dielectric layer until sidewalls of the first semiconductor pattern SP1, second semiconductor pattern SP2, and third semiconductor pattern SP3 are exposed. Therefore, the epitaxial dielectric layer may remain only in the indent region IDR, thereby constituting the inner spacer ISP.

Referring back to FIGS. 9A to 9C, the second recesses RS2 in the stack pattern STP on the second active pattern AP2 may be formed by a method similar to the method used for forming the first recesses RS1. The sacrificial layers SAL exposed by the second recess RS2 may undergo a selective etching process to form indent regions IDE on the second active pattern AP2. The indent regions IDE may cause the second recess RS2 to have a wave-shape inner sidewall. The inner spacers ISP might not be formed in the indent regions IDE on the second active pattern AP2. For example, after the selective etching process, the sacrificial layers SAL may be exposed. A second channel pattern CH2 may include first semiconductor pattern SP1, second semiconductor pattern SP2, and third semiconductor pattern SP3 between two neighboring second recesses RS2. The sacrificial layers SAL, first semiconductor pattern SP1, second semiconductor pattern SP2, and third semiconductor pattern SP3 may be exposed due to the selective etching process.

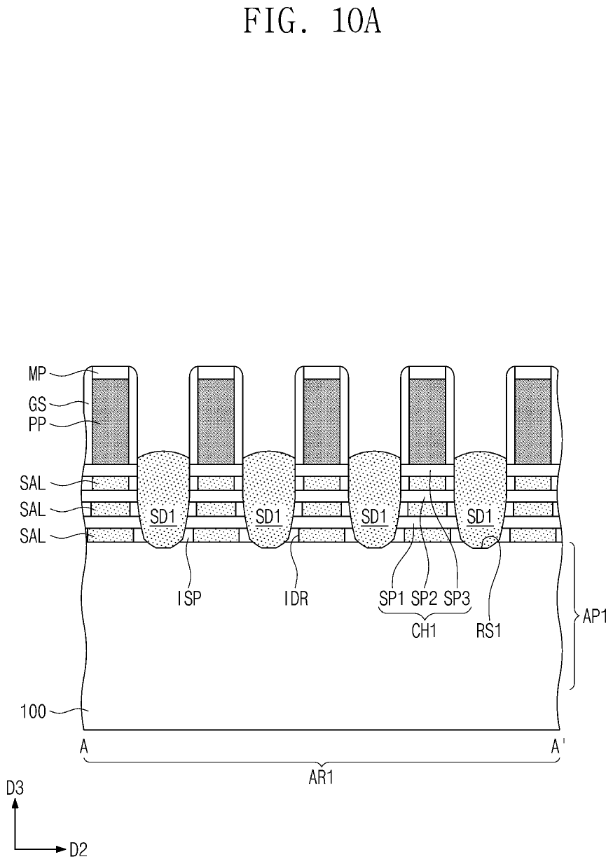

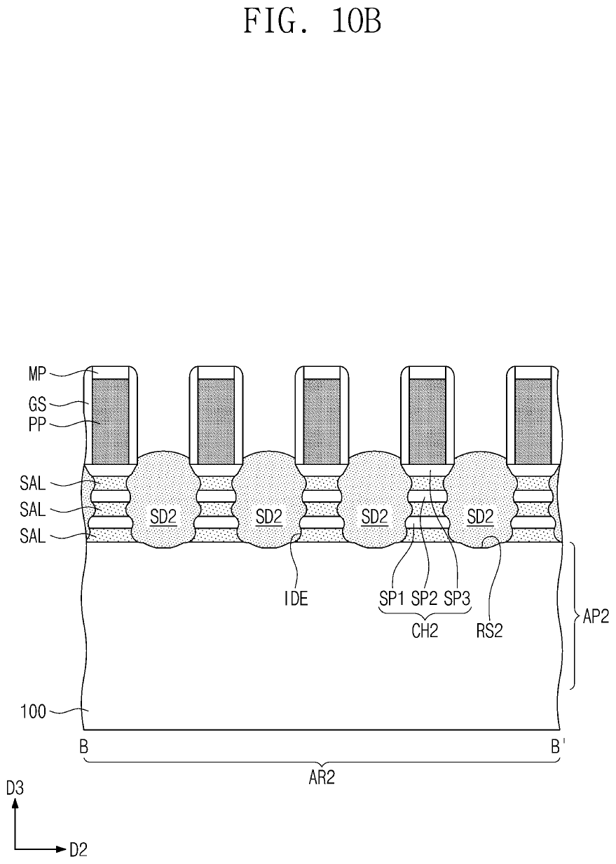

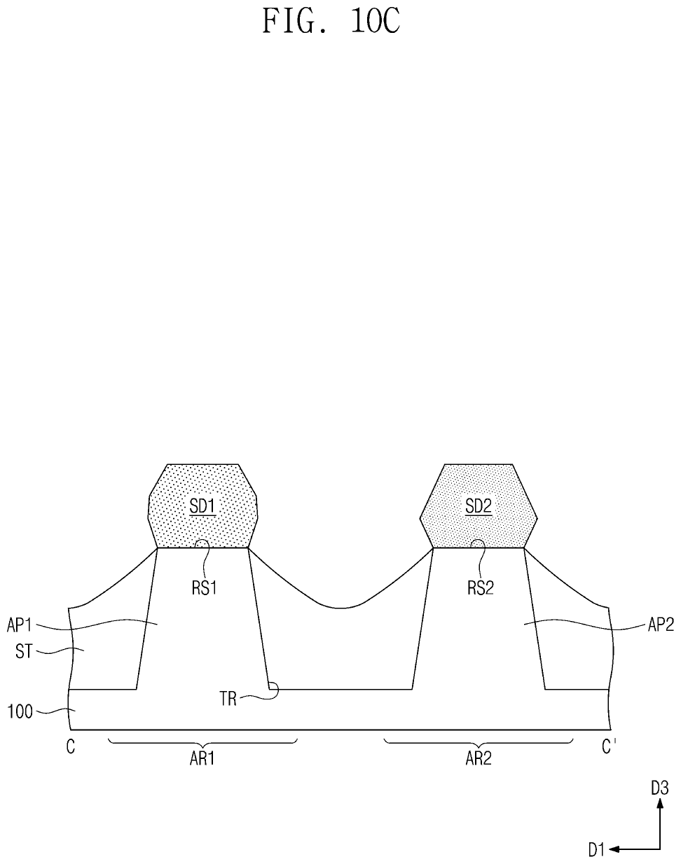

Referring to FIGS. 10A to 10C, first source/drain patterns SD1 may be correspondingly formed in the first recesses RS1. The first source/drain patterns SD1 may be formed in a portion of the first recesses RS1. For example, a selective epitaxial growth (SEG) process may be performed such that an inner sidewall of the first recess RS1 is used as a seed layer to form an epitaxial layer that fills the first recess RS1. The epitaxial layer may be grown from a seed or the substrate 100 and the first semiconductor pattern SP1, second semiconductor pattern SP2, and third semiconductor pattern SP3 exposed by the first recess RS1. For example, the SEG process may include chemical vapor deposition (CVD) or molecular beam epitaxy (MBE).

In an embodiment of the present inventive concepts, the first source/drain pattern SD1 may include the same semiconductor element (e.g., Si) as the semiconductor element of the substrate 100. While the first source/drain pattern SD1 is formed, impurities (e.g., phosphorus, arsenic, or antimony) may be in-situ implanted to allow the first source/drain pattern SD1 to have an n-type characteristic. Alternatively, after the first source/drain pattern SD1 is formed, impurities may be implanted into the first source/drain pattern SD1.

Second source/drain patterns SD2 may be correspondingly formed in the second recesses RS2. The second source/drain patterns SD2 may be formed in a portion of the second recesses RS2. For example, a selective epitaxial growth (SEG) process may be performed such that an inner sidewall of the second recess RS2 is used as a seed to form the second source/drain pattern SD2. As a result, the second source/drain patterns SD2 may have a shape corresponding to the inner sidewall of the second recess RS2.

In an embodiment of the present inventive concepts, the second source/drain pattern SD2 may include a semiconductor element (e.g., SiGe) having lattice constant greater than the lattice constant of a semiconductor element of the substrate 100. While the second source/drain pattern SD2 is formed, impurities (e.g., boron, gallium, or indium) may be in-situ implanted to allow the second source/drain pattern SD2 to have a p-type characteristic. Alternatively, after the second source/drain pattern SD2 is formed, impurities may be implanted into the second source/drain pattern SD2.

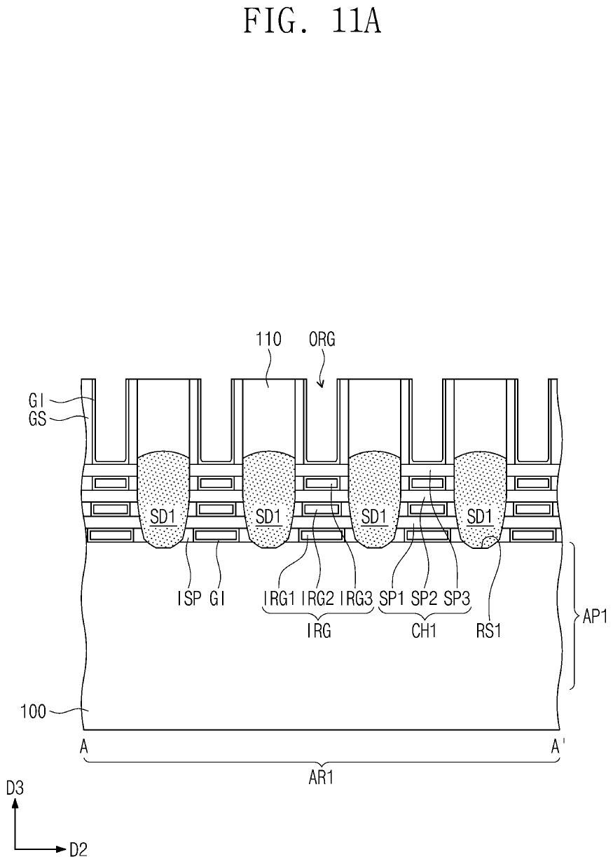

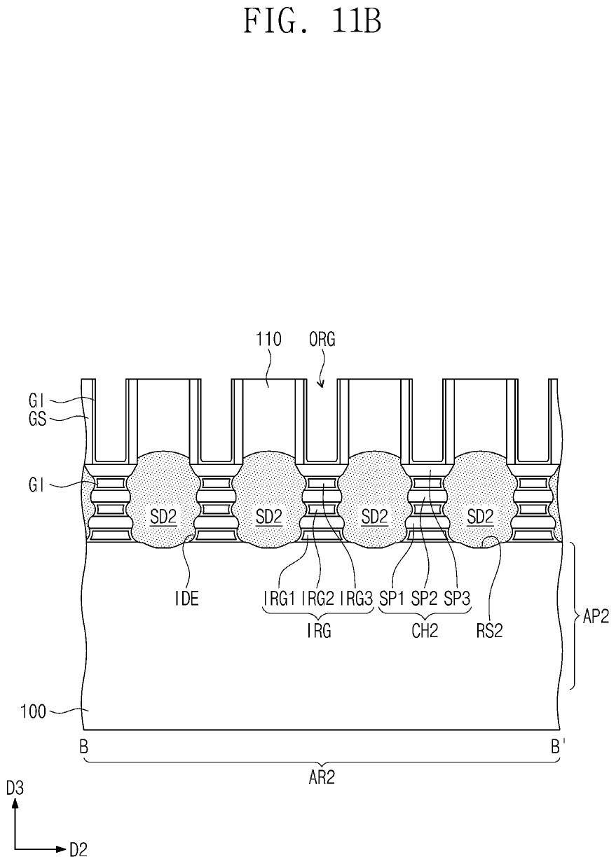

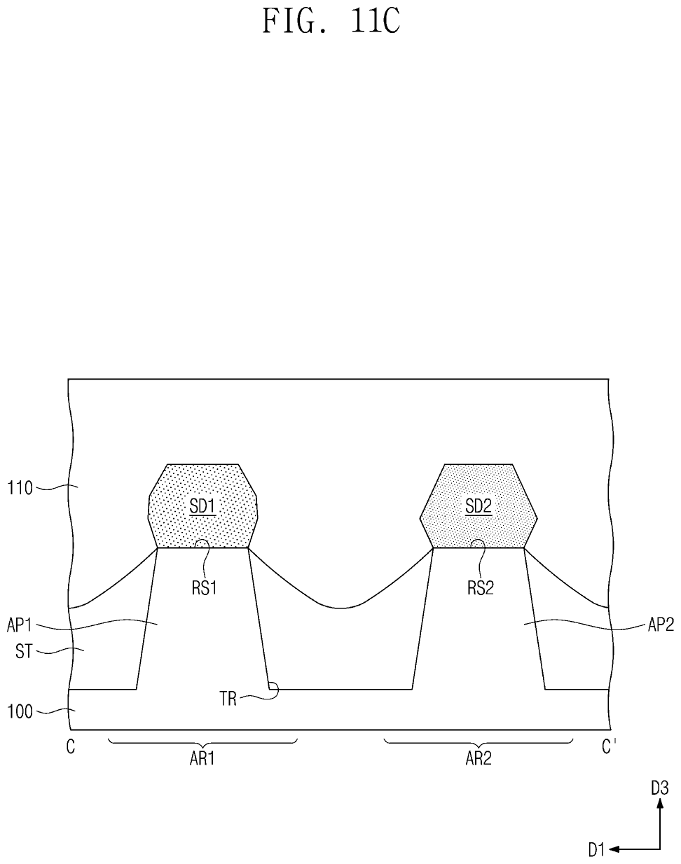

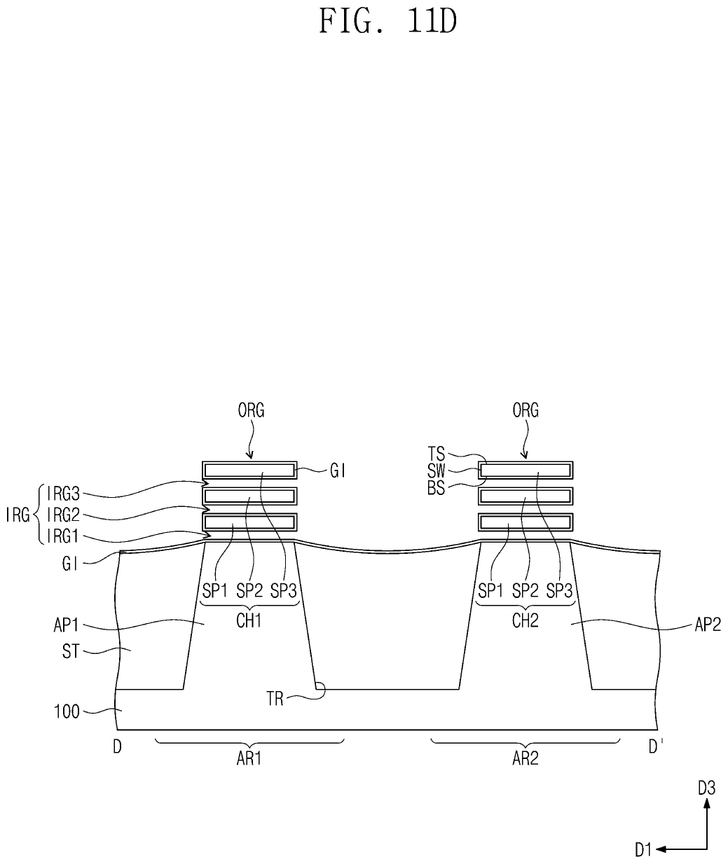

Referring to FIGS. 11A to 11D, a first interlayer dielectric layer 110 may be formed to cover the first source/drain pattern SD1, second source/drain pattern SD2, the hardmask patterns MP, and the gate spacers GS. For example, the first interlayer dielectric layer 110 may include a silicon oxide layer.

The first interlayer dielectric layer 110 may be planarized until top surfaces of the sacrificial patterns PP are exposed. An etch-back or chemical mechanical polishing (CMP) process may be employed to planarize the first interlayer dielectric layer 110. The hardmask patterns MP may be removed during the planarization process. As a result, the first interlayer dielectric layer 110 may have a top surface coplanar with a top surface of the sacrificial patterns PP and a top surface of the gate spacers GS.

The exposed sacrificial patterns PP may be selectively removed. The removal of the sacrificial patterns PP may form an outer region ORG that exposes the first channel pattern CH1 and second channel pattern CH2 (see FIG. 11D). The removal of the sacrificial patterns PP may include performing a wet etching process using an etchant that selectively etches polysilicon.

The sacrificial layers SAL exposed through the outer region ORG may be selectively removed to form inner regions IRG (see FIG. 11D). For example, an etching process that selectively etches the sacrificial layers SAL may be performed such that the sacrificial layers SAL may be removed while having the first semiconductor pattern SP1, second semiconductor pattern SP2, and third semiconductor pattern SP3 remaining in the corresponding location. The etching process may have a high etch rate with respect to silicon-germanium having a relatively high germanium concentration. For example, the etching process may have a high etch rate with respect to silicon-germanium having a germanium concentration greater than about 10 at %.

The etching process may remove the sacrificial layers SAL on the first active region AR1 and second active region AR2. For example, the etching process may be a wet etching process. An etching material used for the etching process may etch the sacrificial layer SAL with relatively high germanium concentrate.

Referring back to FIG. 11D, as the sacrificial layers SAL are selectively removed, the stacked first semiconductor pattern SP1, second semiconductor pattern SP2, and third semiconductor pattern SP3 may remain on each of the first active pattern AP1 and second active pattern AP2. The removal of the sacrificial layers SAL may form the first inner region IRG1, second inner region IRG2, and third inner region IRG3.

For example, the first inner region IRG1 may be formed between the first active pattern AP1 or second active pattern AP2 and the first semiconductor pattern SP1. The second inner region IRG2 may be formed between the first semiconductor pattern SP1 and the second semiconductor pattern SP2. The third inner region IRG3 may be formed between the second semiconductor pattern SP2 and the third semiconductor pattern SP3.

Referring back to FIGS. 11A to 11D, a gate dielectric layer GI may be formed on the exposed first semiconductor pattern SP1, second semiconductor pattern SP2, and third semiconductor pattern SP3. The gate dielectric layer GI may be formed to surround each of the first semiconductor pattern SP1, second semiconductor pattern SP2, and third semiconductor pattern SP3. The gate dielectric layer GI may be formed in each of the first inner region IRG1, second inner region IRG2, and third inner region IRG3. The gate dielectric layer GI may be formed in the outer region ORG.

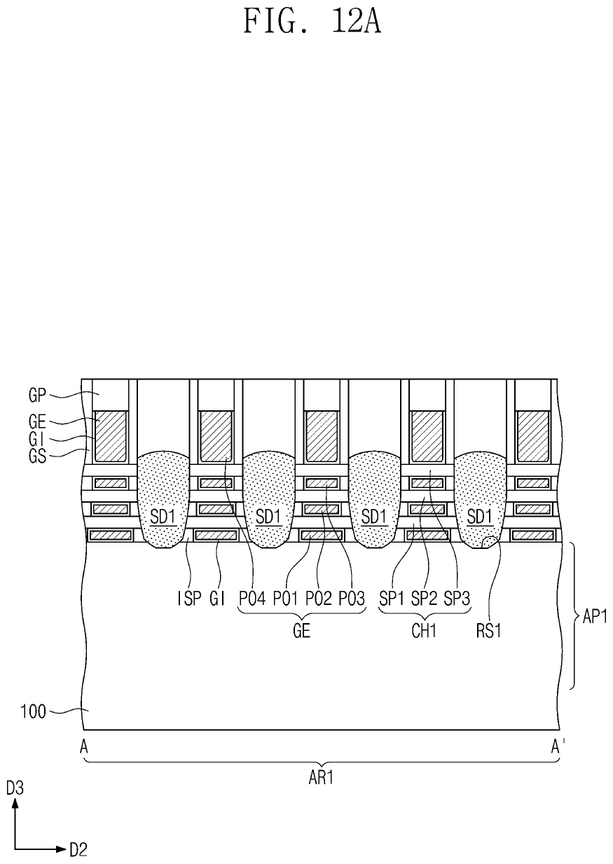

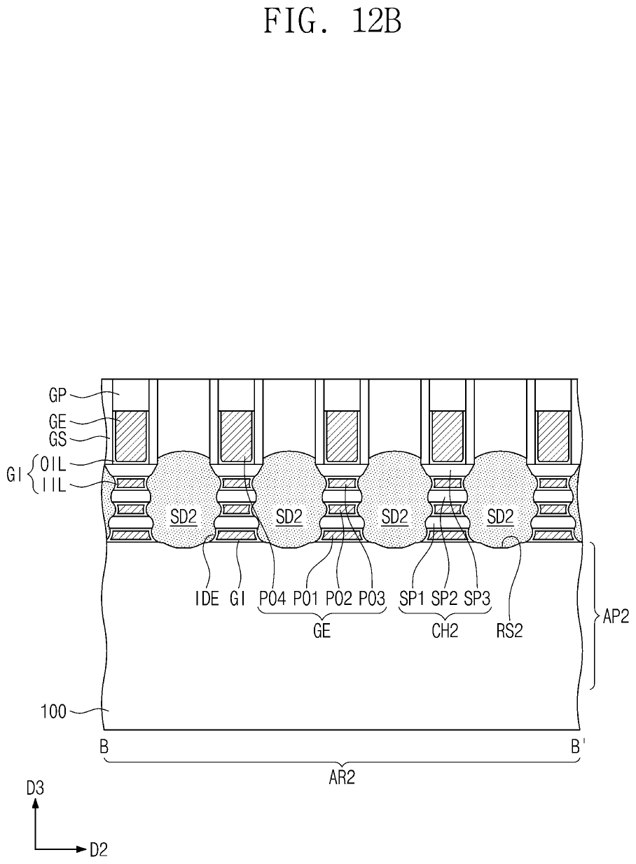

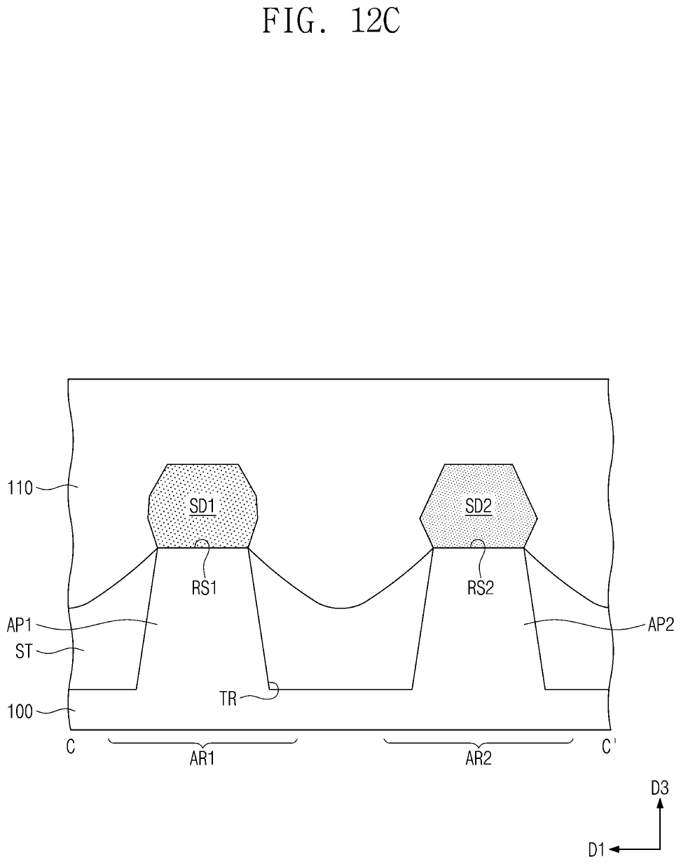

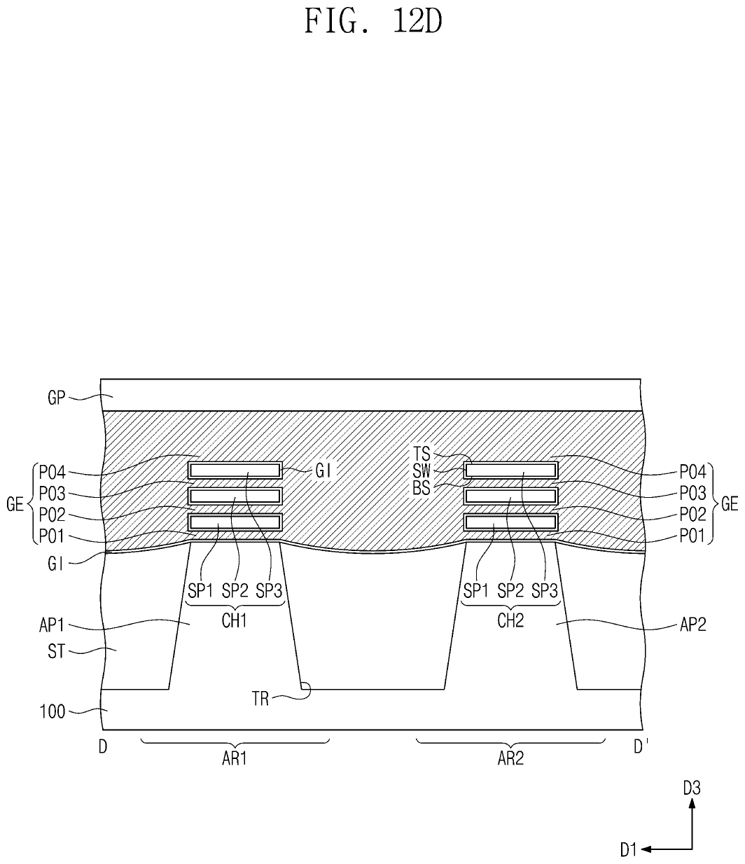

Referring to FIGS. 12A to 12D, a gate electrode GE may be formed on the gate dielectric layer GI. The gate electrode GE may include first inner electrode PO1, second inner electrode PO2, and third inner electrode PO3 that are respectively formed in the first inner region IRG1, second inner region IRG2, and third inner region IRG3, and may also include an outer electrode PO4 formed in the outer region ORG. The outer electrode PO4 may be formed in a lower portion the outer region ORG contacting the gate dielectric layer GI. The gate electrode GE may be recessed to have a reduced height. A gate capping pattern GP may be formed on the recessed gate electrode GE. The gate capping pattern GP may cover the recessed gate electrode GE.

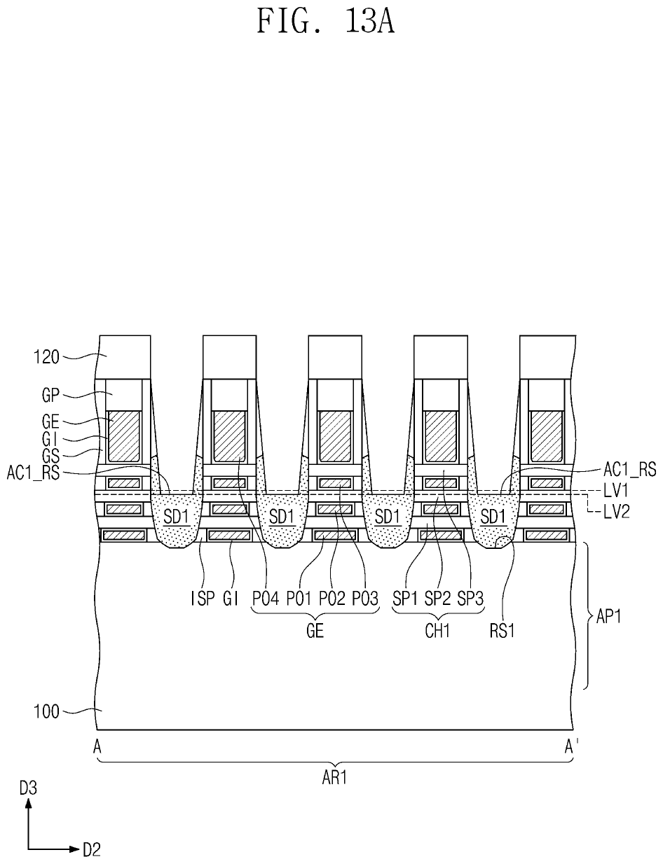

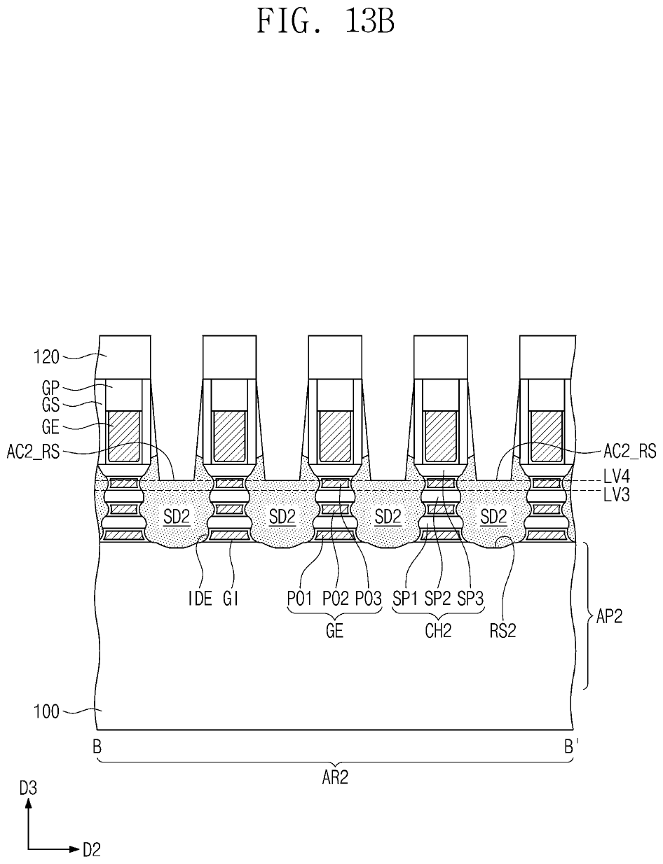

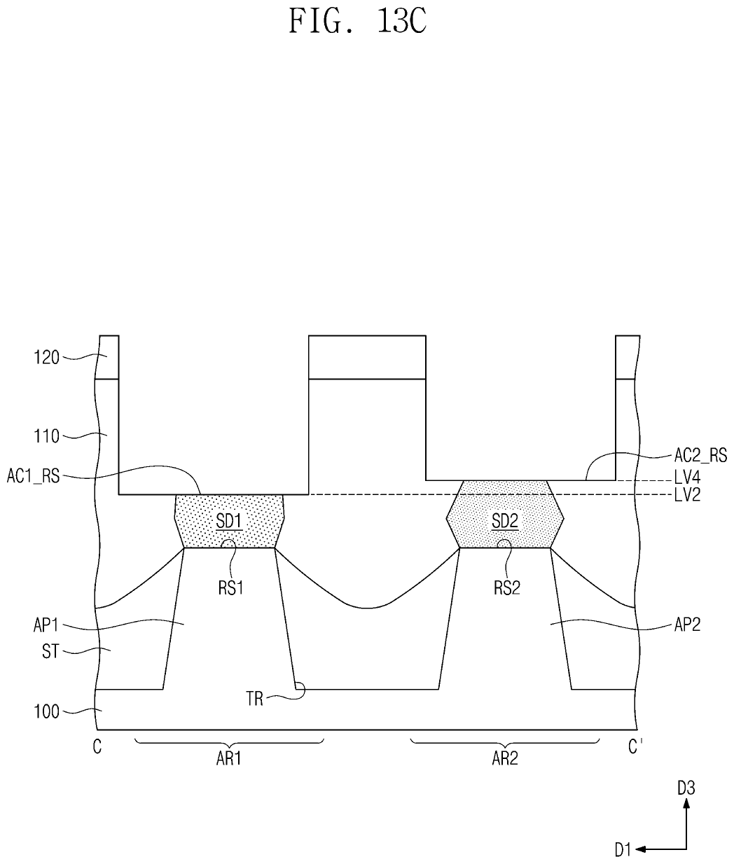

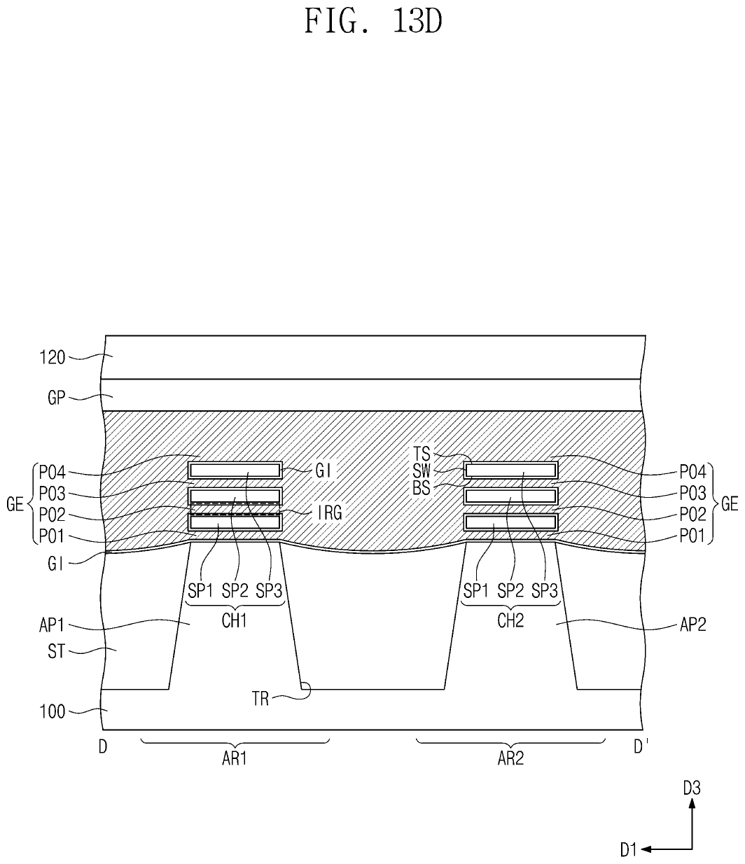

Referring to FIGS. 13A to 13D, a second interlayer dielectric layer 120 may be formed on the first interlayer dielectric layer 110. The second interlayer dielectric layer 120 may include a silicon oxide layer. First recess region AC1_RS and second recess region AC2_RS may be formed to penetrate the second interlayer dielectric layer 120 and the first interlayer dielectric layer 110. The first recess region AC1_RS and second recess region AC2_RS may also penetrate a top portion of the first source/drain pattern SD1 and second source/drain pattern SD2, respectively. The first recess region AC1_RS and second recess region AC2_RS may be formed by performing a dry etching process.

The first recess region AC1_RS may penetrate the first interlayer dielectric layer 110 and second interlayer dielectric layer 120 to extend to an upper portion of the first source/drain pattern SD1. For example, the first recess region AC1_RS may be formed to be inserted into the first source/drain pattern SD1. The first recess region AC1_RS may have a bottom surface lower than a bottom surface of the third inner electrode PO3. A position level LV2, measured in a third direction D3, of the bottom surface of the first recess region AC1_RS may be the same as the second level LV2 of FIG. 5A. A position level LV1, measured in the third direction D3, of a bottom surface of the gate dielectric layer GI that surrounds the third inner electrode PO3 may be the same as the first level LV1 of FIG. 5A.

The second recess region AC2_RS may penetrate the first interlayer dielectric layer 110 and second interlayer dielectric layer 120 to extend to an upper portion of the second source/drain pattern SD2. For example, the second recess region AC2_RS may be formed to be inserted into the second source/drain pattern SD2. The second recess region AC2_RS may have a bottom surface higher than a bottom surface of the third inner electrode PO3. For example, the position level of the bottom surface of the second recess region AC2_RS may be located between a position level LV3 and a level of top surface of the gate dielectric layer GI that surrounds the third inner electrode PO3. A position level LV4, measured in the third direction D3, of the bottom surface of the second recess region AC2_RS may be the same as the fourth level LV4 of FIG. 5B. A position level LV3, measured in the third direction D3, of the bottom surface of the gate dielectric layer GI that surrounds the third inner electrode PO3 may be the same as the third level LV3 of FIG. 5B.

Referring back to FIG. 13C, the position level LV2 of the bottom surface of the first recess region AC1_RS may be lower than the position level LV4 of the bottom surface of the second recess region AC2_RS. This may be caused by the fact that a subsequently described cyclic etching process has an etch rate that is greater on an NMOSFET region than on a PMOSFET region.

Referring back to FIGS. 5A to 5D, first active contact AC1 and second active contact AC2 may be formed to penetrate the second interlayer dielectric layer 120 and the first interlayer dielectric layer 110 to come into electrical connection with the first source/drain pattern SD1 and second source/drain pattern SD2. A gate contact GC may be formed to penetrate the second interlayer dielectric layer 120 and the gate capping pattern GP to come into electrical connection with the gate electrode GE.

The formation of the first active contact AC1, second active contact AC2, and the gate contact GC may include forming barrier patterns (e.g., BM1, BM2, and BM) and forming conductive patterns (e.g., FM1, FM2, and FM) on the barrier patterns (e.g., BM1, BM2, and BM, respectively). The barrier patterns (e.g., BM1, BM2, and BM) may be conformally formed and may include a metal layer and a metal nitride layer. The conductive patterns (e.g., FM1, FM2, and FM) may include metal having low resistance.

Separation structures DB may be correspondingly formed on first boundary BD1 and second boundary BD2 of the single height cell SHC. The separation structure DB may extend from the second interlayer dielectric layer 120 through the gate electrode GE into the first active pattern AP1 and/or the second active pattern AP2. The separation structure DB may include a dielectric material, such as a silicon oxide layer or a silicon nitride layer.

A third interlayer dielectric layer 130 may be formed on the gate contacts GC, the first active contact, and second active contact AC2. A first metal layer M1 may be formed in the third interlayer dielectric layer 130. For example, the third interlayer dielectric layer 130 may cover the second interlayer dielectric layer 120, the first interlayer dielectric layer 110, the gate contacts GC, the first active contact, second active contact AC2, and the separation structures DB. A fourth interlayer dielectric layer 140 may be formed on the third interlayer dielectric layer 130. A second metal layer M2 may be formed in the fourth interlayer dielectric layer 140.

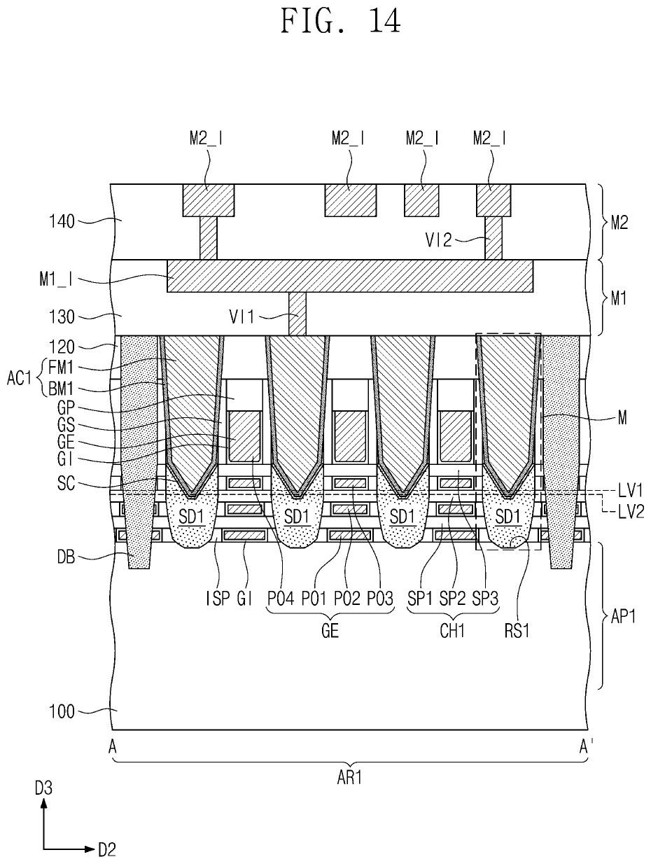

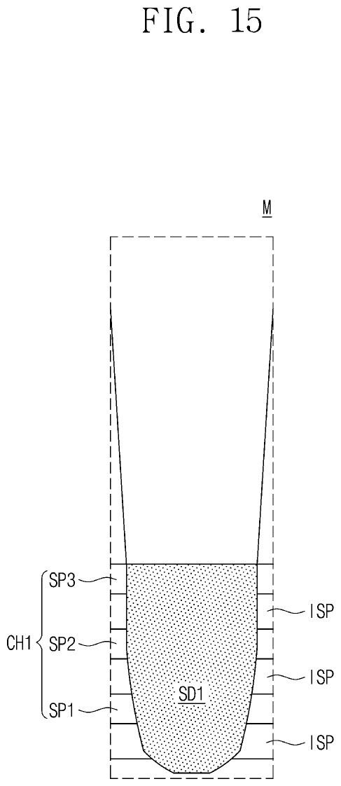

FIG. 14 illustrates a cross-sectional view showing an active contact according to an embodiment of FIG. 5A. FIGS. 15 to 20 illustrate a method of forming an active contact at the enlarged cross-sectional views of section M depicted in FIG. 14. Detailed description of technical features repetitive to those discussed with reference to FIGS. 1 to 6B may be omitted, and a difference thereof will be discussed in detail. Omitted details are understood to be the same as described for corresponding elements elsewhere in the disclosure.

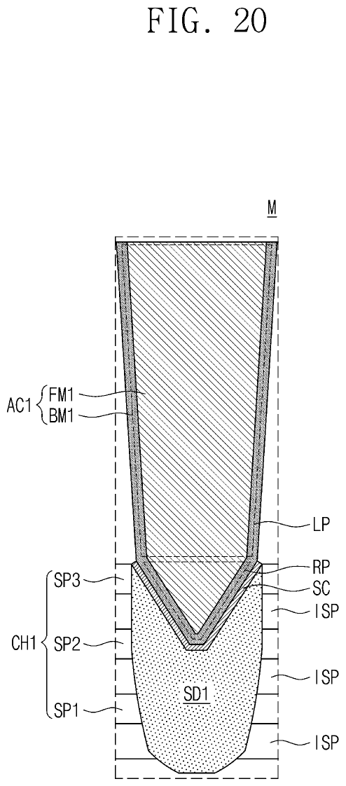

Referring to FIGS. 14 and 20, the first active contact AC1 may include a first conductive pattern FM1 and a first barrier pattern BM1 that surrounds the first conductive pattern FM1. The first barrier pattern BM1 may cover lateral and bottom surfaces of the first conductive pattern FM1.

The first active contact AC1 may include a connection part LP and a protrusion part RP (see. FIG. 20). The connection part LP may electrically connect the first source/drain pattern SD1 to the first wiring line M1_I in the first metal layer M1. The connection part LP may penetrate the first interlayer dielectric layer 110 and the second interlayer dielectric layer 120. The connection part LP may have a top surface coplanar with a top surface of the second interlayer dielectric layer 120. A width, measured in the second direction D2, of the connection part LP may decrease when connection part LP is towards the substrate 100. For example, the width of the connection part LP may decrease linearly from the upper surface that is coplanar with a top surface of the second interlayer dielectric layer 120 towards lower surface that is closer to the substrate.

The protrusion part RP may be inserted into the first source/drain pattern SD1. For example, the protrusion part RP may extend from the connection part LP to expand into the first source source/drain pattern SD1. A width, measured in the second direction D2, of the protrusion part RP may decrease with decreasing distance towards the substrate 100. The width, measured in the second direction D2, of the protrusion part RP may be less than the width, measured in the second direction D2, of the connection part LP. The width, measured in the second direction D2, of the protrusion part RP may be the same as the width, measured in the second direction D2, of the connection part LP at the connection point of between the protrusion part RP and connection part LP. For example, the width at a bottom surface of the connection part LP may be the same as that at a top surface of the protrusion part RP.

The protrusion part RP may be adjacent to the first source/drain pattern SD1, and the first active contact AC1 and the first source/drain pattern SD1 may be electrically connected to each other. The silicide layer SC may be interposed between the protrusion part RP and the first source/drain pattern SD1. The silicide layer SC may be formed to correspond to a shape of the protrusion part RP. As a result, the first active contact AC1 may be electrically connected to the first source/drain pattern SD1 through the silicide layer SC. The silicide layer SC may reduce a contact resistance between the first active contact AC1 and the first source/drain pattern SD1.

According to an embodiment, the of the present inventive concepts protrusion part RP may have a flat bottom surface, one lateral surface inclined in one direction, and another lateral surface inclined in an opposite direction. According to an embodiment of the present inventive concepts, the protrusion part RP may have no flat bottom surface. For example, the protrusion part RP may have a pointed shape. The pointed shape of the protrusion part RP may be formed by a cyclic etching process which will be discussed below.

With reference to FIGS. 15 to 20, a cyclic etching process to form the first active contact AC1 of FIG. 14 is described. FIGS. 15 to 20 illustrate a method of a cyclic process at the enlarged views of section M depicted in FIG. 14.

A cyclic etching process may include a first etching stage, a first coating stage, a second etching stage, a second coating stage, a third etching stage, and a fourth etching stage. Referring to FIG. 15, the first etching stage may be a step of performing a dry etching process in which an interlayer dielectric layer (e.g., the first and second interlayer dielectric layers 110 and 120) is penetrated to expose a top surface of the first source/drain pattern SD1. The first etching stage may expose a lateral surface of the interlayer dielectric layer. The first etching stage may be performed by setting a target amount of etching or an amount of process time based on etch rate.

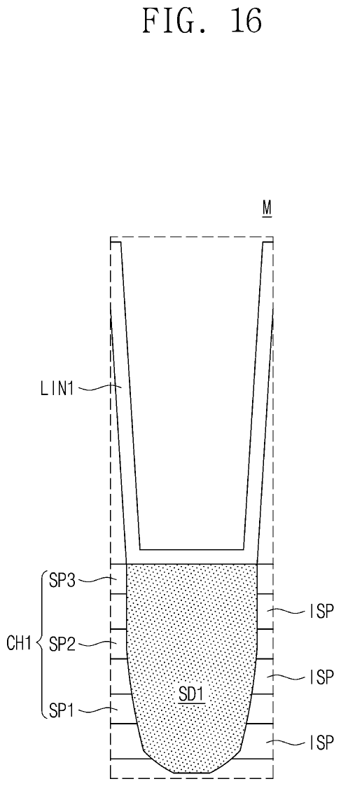

Referring to FIG. 16, the first coating stage may be a step of uniformly forming a first liner layer LIN1 on the exposed lateral surface of the interlayer dielectric layer and on the exposed top surface of the first source/drain pattern SD1. In the first coating stage, a process condition may be adjusted to conformally form the first liner layer LIN1. The first liner layer LIN1 may include silicon oxide, silicon nitride, or silicon oxynitride. The first liner layer LIN1 may have a thickness of about 5 Å to about 15 Å.

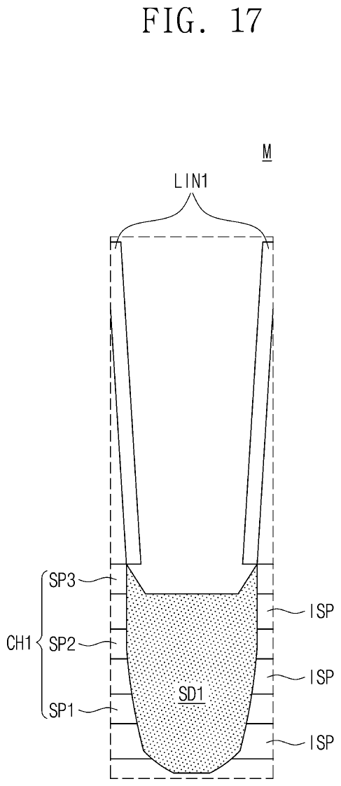

Referring to FIG. 17, the second etching stage may be a step of performing a dry etching process to penetrate a portion of a bottom surface of the first liner layer LIN1. The second etching stage may expose a portion of the first liner layer LIN1 adjacent to the first source/drain pattern SD1. In the second etching stage, the first source/drain pattern SD1 may be partially recessed through the exposed portion. A recess region formed by the second etching stage may have a trapezoidal shape. The second etching stage may be adjusted to have a process condition in which an amount of etching of the first source/drain pattern SD1 is greater than an amount of etching of the second source/drain pattern (see SD2 of FIG. 5B).

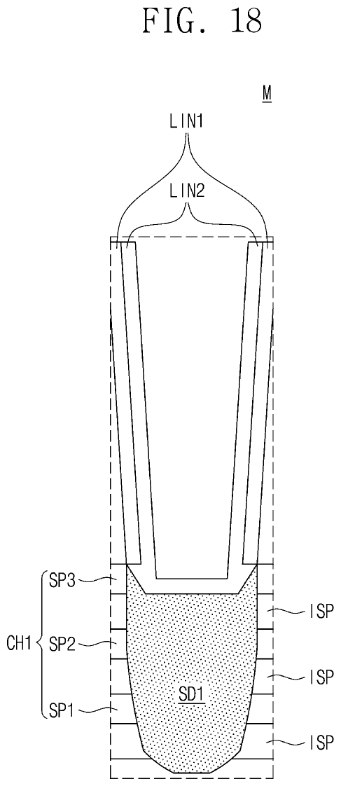

Referring to FIG. 18, the second coating stage may be a step of uniformly forming a second liner layer LIN2 on lateral and bottom surfaces of the first liner layer LIN1 and on the top surface of the first source/drain pattern SD1 that is exposed through the second etching stage. In the second coating stage, a process condition may be adjusted to conformally form the second liner layer LIN2. The second liner layer LIN2 may include silicon oxide, silicon nitride, or silicon oxynitride. The second liner layer LIN2 may have a thickness of about 5 Å to about 15 Å. For example, the thickness of the second liner layer LIN2 may be substantially the same as the thickness of the first liner layer LIN1.

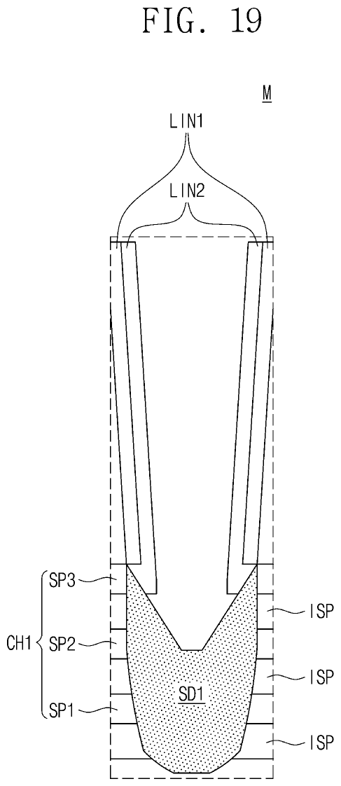

Referring to FIG. 19, the third etching stage may be a step of performing a dry etching process to penetrate a portion of a bottom surface of the second liner layer LIN2. The third etching stage may expose a portion of the second liner layer LIN2 adjacent to the first source/drain pattern SD1. In the third etching stage, the first source/drain pattern SD1 may be further partially recessed through the exposed portion. The third etching stage may be adjusted to have a process condition in which an amount of etching of the first source/drain pattern SD1 is greater than an amount of etching of the second source/drain pattern (see SD2 of FIG. 5B).

A recess region formed by the third etching stage may have a trapezoidal shape. A width, measured in the second direction D2, of the recess region may be less than a width, measured in the second direction D2, of the recess region formed through the second etching stage. The recess region formed through the third etching stage may have a flat bottom surface, one lateral surface inclined in one direction, and another lateral surface inclined in an opposite direction. According to an embodiment of the present inventive concepts, the recess region formed through the third etching stage might not have flat bottom surface. For example, the recess region formed through the third etching process may have a pointed shape towards the substrate 100.

Referring to FIG. 20, the fourth etching stage may be a step of performing a dry or wet etching process to remove the first and second liner layers LIN1 and LIN2. The fourth etching stage may be performed by setting a target amount of etching or an amount of process time based on etch rate. After the removal of the first and second liner layers LIN1 and LIN2, a first active contact AC1 may be formed. According to an embodiment of the present inventive concepts, the first active contact AC1 may be formed in recess region without the removal of the first liner layer LIN1 and second liner layer LIN2 (see FIGS. 6A and 6B).

Through the cyclic etching process, an amount of etching of the first source/drain pattern (see SD1 of FIG. 5A) on an NMOSFET region may be greater than an amount of etching of the second source/drain pattern (see SD2 of FIG. 5B) on a PMOSFET region. As an amount of etching is adjusted based on location, the resistance values of the first source/drain patterns SD1 and second source/drain pattern SD2 may be controlled. In addition, a bowing phenomenon in which a recess region of a source/drain pattern is isotropically etched may be prevented. A semiconductor device may thus be prevented from punch issues of source/drain patterns adjacent to channels. Accordingly, the occurrence of leakage current may be suppressed in a semiconductor device.

As a result, a semiconductor device according to the present inventive concepts may be configured such that a resistance value of a source/drain pattern is reduced to increase reliability of the semiconductor device. Moreover, as the adjustment of resistance values is achieved and the occurrence of leakage current is prevented, electrical properties of a semiconductor device may be improved.

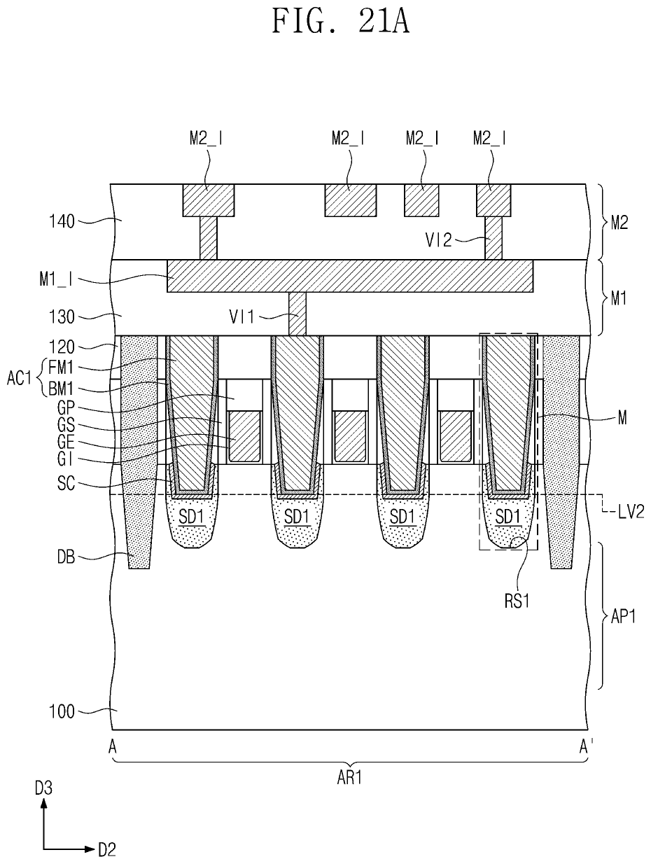

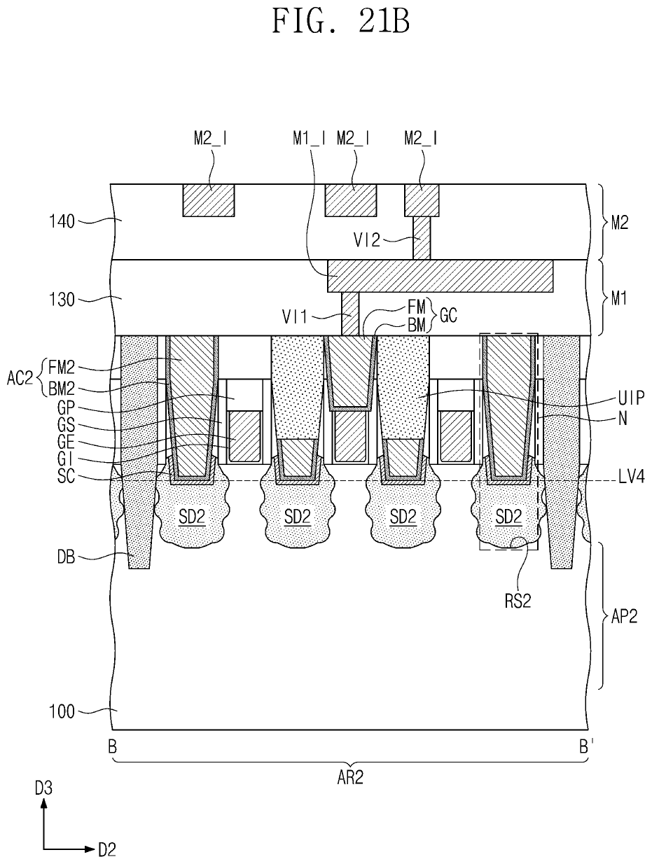

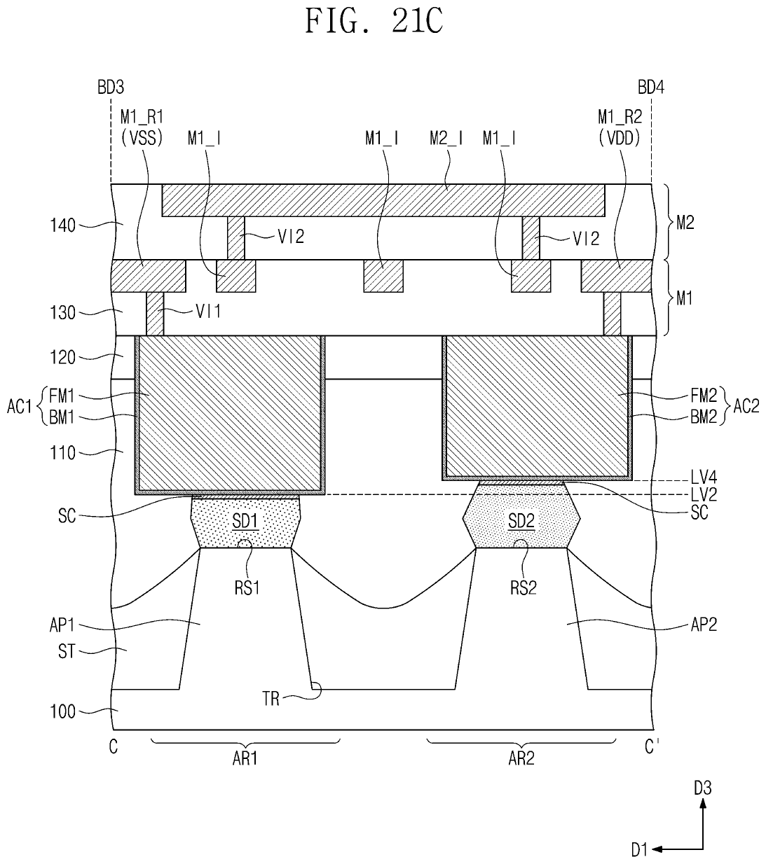

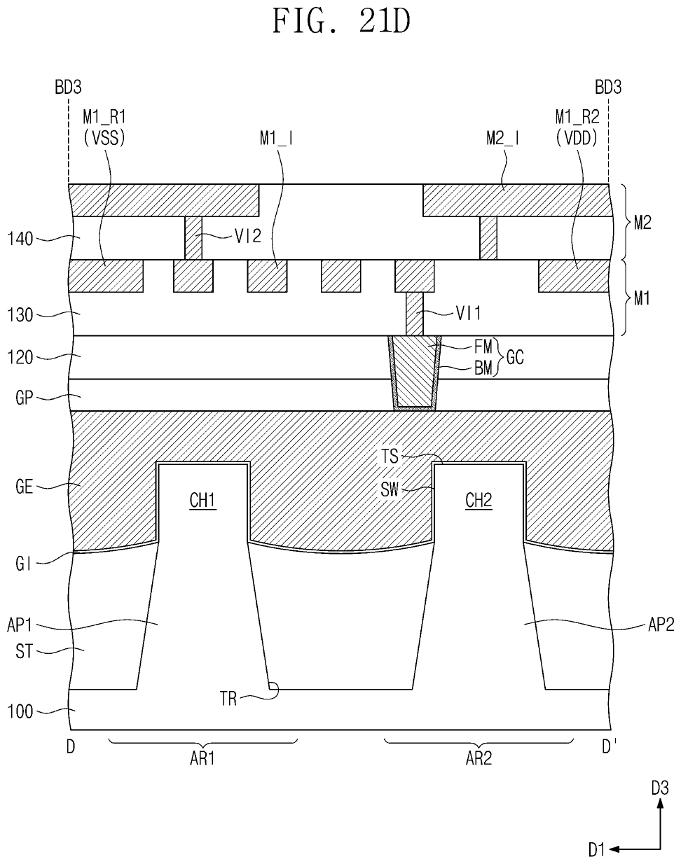

FIGS. 21A, 21B, 21C, and 21D illustrate cross-sectional views taken along lines A-A′, B-B′, C-C′, and D-D′, respectively, of FIG. 4 of a semiconductor device according to some embodiments of the present inventive concepts. Referring to FIGS. 4 and 21A to 21D, a device isolation layer ST may define a first active pattern AP1 and a second active pattern AP2 on an upper portion of a substrate 100. The first active pattern AP1 may be disposed on a first active region AR1, and the second active pattern AP2 may be disposed on a second active region AR2. For example, the first active region AR1 may be an NMOSFET region, and the second active region AR2 may be a PMOSFET region.

The device isolation layers ST may cover a lower sidewall of each of the first active pattern AP1 and second active pattern AP2. Each upper portion of the first active pattern AP1 and second active pattern AP2 may upwardly protrude from the device isolation layer ST (see FIG. 21C).

The first active pattern AP1 may include first source/drain patterns SD1 on an upper portion thereof and a first channel pattern CH1 between the first source/drain patterns SD1. The second active pattern AP2 may include second source/drain patterns SD2 on an upper portion thereof and a second channel pattern CH2 between the second source/drain patterns SD2.

Referring back to FIG. 21C, each of the first channel pattern CH1 and second channel pattern CH2 might not include any of the stacked first semiconductor pattern SP1, second semiconductor pattern SP2, and third semiconductor pattern SP3 discussed above with reference to FIGS. 5A to 5D. Each of the first channel pattern CH1 and second channel pattern CH2 may have a semiconductor pillar shape that protrudes upwardly from the device isolation layer ST.

A gate electrode GE may be disposed on a top surface TS and opposite sidewalls SW of each of the first channel pattern CH1 and second channel pattern CH2. For example, a transistor according to some embodiments may be a three-dimensional field effect transistor (e.g., FinFET) in which the gate electrode GE surrounds the first channel pattern CH1 and second channel pattern CH2 in three dimensions.

A first interlayer dielectric layer 110 and a second interlayer dielectric layer 120 may be disposed on an entire surface of the substrate 100. First active contact AC1 and second active contact AC2 may penetrate the first interlayer dielectric layer 110 and second interlayer dielectric layer 120 to contact the first source/drain pattern SD1 and second source/drain pattern SD2, respectively. A gate contact GC may penetrate the second interlayer dielectric layer 120 and the gate capping pattern GP to contact the gate electrode GE. A detailed description of the first active contact AC1 and second active contact AC2 and the gate contacts GC may be substantially the same as that discussed above with reference to FIGS. 4 and 5A to 5D.

A third interlayer dielectric layer 130 may be disposed on the second interlayer dielectric layer 120. A fourth interlayer dielectric layer 140 may be disposed on the third interlayer dielectric layer 130. A first metal layer M1 may be disposed in the third interlayer dielectric layer 130. A second metal layer M2 may be disposed in the fourth interlayer dielectric layer 140. A detailed description of the first metal layer M1 and the second metal layer M2 may be substantially the same as that discussed above with reference to FIGS. 4 and 5A to 5D.

In a three-dimensional field effect transistor provided according to the present inventive concepts, an amount of etching of source/drain patterns may be adjusted based on NMOSFET/PMOSFET regions, and thus resistance values of the source/drain patterns may be controlled. In addition, a bowing phenomenon in which a recess region of the source/drain pattern is isotropically etched may be prevented. In the present inventive concepts, because an amount of etching of the source/drain pattern is adjusted, and because an active contact without the bowing phenomenon is provided, a semiconductor device may have improved electrical properties and increased reliability.

Although the present inventive concepts have been described in connection with some embodiments of the present inventive concepts illustrated in the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. A semiconductor device, comprising:
a substrate including an active pattern;
a channel pattern disposed on the active pattern, wherein the channel pattern includes a plurality of semiconductor patterns that are spaced apart from each other and are vertically stacked on each other;
a first source/drain pattern and a second source/drain pattern that are connected to the plurality of semiconductor patterns, wherein the first source/drain pattern is disposed on an NMOSFET region of a first active region and the second source/drain pattern is disposed on a PMOSFET region of a second active region;
a gate electrode disposed on the plurality of semiconductor patterns, wherein the gate electrode includes inner electrodes disposed between neighboring semiconductor patterns of the plurality of semiconductor patterns and an outer electrode disposed on an uppermost semiconductor pattern; and
a first active contact electrically connected to the first source/drain pattern and a second active contact electrically connected to the second source/drain pattern,
wherein a first recess depth of the first active contact is about 1.2 times to about 2.5 times as deep as a second recess depth of the second active contact.

2. The semiconductor device of claim 1, wherein the first recess depth ranges from about 10.0 nm to about 12.0 nm.

3. The semiconductor device of claim 1, wherein the second recess depth ranges from about 5.0 nm to about 7.0 nm.

4. The semiconductor device of claim 1, wherein
the first active contact includes a first conductive pattern and a first barrier pattern that surrounds the first conductive pattern, and
wherein the first barrier pattern covers sidewalls and a bottom surface of the first conductive pattern.

5. The semiconductor device of claim 4, wherein
the first conductive pattern includes aluminum, copper, tungsten, molybdenum, and/or cobalt, and
wherein the first barrier pattern includes a metal layer and a metal nitride layer.

6. The semiconductor device of claim 5, wherein
the metal layer includes titanium, tantalum, tungsten, nickel, cobalt, and/or platinum, and
wherein the metal nitride layer includes a titanium nitride (TiN) layer, a tantalum nitride (TaN) layer, a tungsten nitride (WN) layer, a nickel nitride (NiN) layer, a cobalt nitride (CoN) layer, and/or a platinum nitride (PtN) layer.

7. The semiconductor device of claim 1, wherein
the second active contact includes a second conductive pattern and a second barrier pattern that surrounds the second conductive pattern, and
wherein the second barrier pattern covers sidewalls and a bottom surface of the second conductive pattern.

8. The semiconductor device of claim 7, wherein
the second conductive pattern includes aluminum, copper, tungsten, molybdenum, and/or cobalt, and
wherein the second barrier pattern includes a metal layer and a metal nitride layer.

9. The semiconductor device of claim 8, wherein
the metal layer includes titanium, tantalum, tungsten, nickel, cobalt, and/or platinum, and
wherein the metal nitride layer includes a titanium nitride (TiN) layer, a tantalum nitride (TaN) layer, a tungsten nitride (WN) layer, a nickel nitride (NiN) layer, a cobalt nitride (CoN) layer, and/or a platinum nitride (PtN) layer.

10. The semiconductor device of claim 1, further comprising:
a gate contact electrically connected to the outer electrode,
wherein the second active contact adjacent to the gate contact includes:
a second conductive pattern;
a second barrier pattern that covers sidewalls and a bottom surface of the second conductive pattern; and
an upper dielectric pattern disposed on the second conductive pattern and the second barrier pattern.

11. A semiconductor device, comprising:
a substrate including an active pattern;
a channel pattern disposed on the active pattern, wherein the channel pattern includes a plurality of semiconductor patterns that are spaced apart from each other and are vertically stacked on each other;
a first source/drain pattern and a second source/drain pattern that are connected to the plurality of semiconductor patterns, wherein the first source/drain pattern is disposed on an NMOSFET region of a first active region, and the second source/drain pattern is disposed on a PMOSFET region of a second active region;
a gate electrode disposed on the plurality of semiconductor patterns, wherein the gate electrode includes inner electrodes disposed between neighboring semiconductor patterns of the plurality of semiconductor patterns and an outer electrode disposed on an uppermost semiconductor pattern; and
a first active contact electrically connected to the first source/drain pattern and a second active contact electrically connected to the second source/drain pattern,
wherein the inner electrodes include a first inner electrode, a second inner electrode, and a third inner electrode that are sequentially stacked,
wherein a bottom surface of the first active contact is disposed at a level lower than a level of a bottom surface of the third inner electrode, and
wherein a bottom surface of the second active contact is disposed at a level higher than the level of the bottom surface of the third inner electrode.

12. The semiconductor device of claim 11, wherein the level of the bottom surface of the second active contact is higher than the level of the bottom surface of the third inner electrode and lower than a level of a top surface of the third inner electrode.

13. The semiconductor device of claim 11, further comprising a gate dielectric layer disposed between the gate electrode and the plurality of semiconductor patterns,
wherein the level of the bottom surface of the first active contact is lower than a level of a bottom surface of the gate dielectric layer that surrounds the third inner electrode.

14. The semiconductor device of claim 13, wherein the level of the bottom surface of the second active contact is higher than the level of the bottom surface of the gate dielectric layer that surrounds the third inner electrode and lower than a level of a top surface of the gate dielectric layer that surrounds the third inner electrode.

15. The semiconductor device of claim 11, wherein
the first active contact includes a first conductive pattern and a first barrier pattern that surrounds the first conductive pattern,
wherein the second active contact includes a second conductive pattern and a second barrier pattern that surrounds the second conductive pattern,
wherein the first barrier pattern covers sidewalls and a bottom surface of the first conductive pattern, and
wherein the second barrier pattern covers sidewalls and a bottom surface of the second conductive pattern.

16. The semiconductor device of claim 15, wherein a level of a bottom surface of the first barrier pattern is lower than a level of a bottom surface of the second barrier pattern.

17. The semiconductor device of claim 11, further comprising:
a device isolation layer that defines the active pattern;
a gate dielectric layer disposed between the gate electrode and corresponding neighboring semiconductor patterns;
an inner spacer disposed between the gate dielectric layer and the first source/drain pattern;
a gate spacer disposed on sidewalls of the gate electrode;
a gate capping pattern disposed on a top surface of the gate electrode;
an interlayer dielectric layer disposed on the gate capping pattern;
a metal-semiconductor compound layer disposed between the first active contact and the first source/drain pattern, and disposed between the second active contact and the second source/drain pattern;
a gate contact that penetrates the interlayer dielectric layer and the gate capping pattern and is electrically connected to the gate electrode;
a first metal layer disposed on the interlayer dielectric layer; and
a second metal layer on the first metal layer,
wherein the first metal layer includes a power line and first wiring lines,
wherein the first wiring lines are electrically connected to the first active contact, the second active contact, and the gate contact, and
wherein the second metal layer includes second wiring lines electrically connected to the first metal layer.

18. A semiconductor device, comprising:
a substrate including an active pattern;
a channel pattern disposed on the active pattern, wherein the channel pattern includes a plurality of semiconductor patterns that are spaced apart from each other and are vertically stacked on each other;
a source/drain pattern connected to the plurality of semiconductor patterns;
a gate electrode disposed on the plurality of semiconductor patterns;
an active contact electrically connected to the source/drain pattern; and
a metal line disposed on the active contact and the gate electrode,
wherein the active contact includes:
a connection part that connects the metal line and the source/drain pattern; and
a protrusion part inserted into the source/drain pattern and is electrically connected to the source/drain pattern,
wherein a width of the protrusion part decreases towards the substrate, and
wherein a level of a bottom surface of the protrusion part is lower than a level of a bottom surface of an uppermost semiconductor pattern of the plurality of semiconductor patterns.

19. The semiconductor device of claim 18, further comprising:
a silicide layer disposed between a barrier pattern and the source/drain pattern,
wherein the active contact includes a conductive pattern and the barrier pattern that surrounds the conductive pattern, and
wherein a shape of the suicide layer corresponds to a shape of the protrusion part.

20. The semiconductor device of claim 18, wherein the protrusion part has a pointed shape having a pointed bottom surface towards the substrate.
